(19) United States
(12) Patent Application Publication
(10) Pub. No.: US 2007/0075419 A1
(43) Pub. Date: Apr. 5, 2007

(54) Semiconductor device having metallic lead and electronic device having lead frame

(75) Inventors: Yutaka Fukuda, Kariya-city (JP); Mitsuhiro Saitou, Obu-city (JP); Toshihiro Nagaya, Okazaki-city (JP); Yukihiro Maeda, Kasugai-city (JP); Norihisa Imaizumi, Hoi-gun (JP); Yasutomi Asai, Okazaki-city (JP); Yasutomi Asai, Okazaki-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/515,045

(22) Filed: Sep. 5, 2006

(30) Foreign Application Priority Data
Sep. 6, 2005 (JP) 2005-257822
Nov. 9, 2005 (JP) 2005-324870
Mar. 7, 2006 (JP) 2006-061292

(51) Int. Cl. H01L 23/34

(52) U.S. Cl. 257/717

(57) ABSTRACT

A semiconductor device includes: first to fourth vertical type semiconductor elements having first and second electrodes; a metallic lead; a resin mold; a circuit board; an electric circuit on the circuit board; and an electronic chip on the circuit board. The electronic chip drives and controls each semiconductor element through the electric circuit. The first to fourth semiconductor elements are arranged to be a stack construction in the resin mold. The first to fourth semiconductor elements provide a H-bridge circuit. Each of the first and second electrodes in each semiconductor element is directly connected to the metallic lead so that heat generated in the semiconductor element is radiated through the metallic lead.

### CROSS REFERENCE TO RELATED APPLICATIONS

This application is based on Japanese Patent Application No. 2005-257822 filed on Sep. 6, 2005, No. 2005-324870 filed on Nov. 9, 2005, and No. 2006-61292 filed on Mar. 7, 2006, the disclosures of which are incorporated herein by reference.

### FIELD OF THE INVENTION

The present invention relates to a semiconductor device having a metallic lead and an electronic device having a lead frame.

### BACKGROUND OF THE INVENTION

The Applicants of the present invention has proposed such a semiconductor device 200 as shown in FIGS. 10A and 10B in previously filed Japanese Patent Application No. 2004-291398, which corresponds to US 2005-0231925-A1. This semiconductor devices 200 is applied to an HIC (Hybrid Integrated Circuit) which drives a driving motor of a power window.

FIG. 10A is a plan view for indicating the semiconductor device 200, and FIG. 10B is a sectional view for showing the semiconductor device 200, taken only a line XB-XB of FIG. 10A. As indicated in FIG. 10A, the semiconductor device 200 has been constituted by employing a first electronic element 210, a second electronic element 220, a heat sink 230, a first wiring board 240, a second wiring board 250, a lead 261, and another lead 262.

The first electronic element 210 has been provided with a microcomputer 211 and a control IC 212 as control elements. Also, in the second electronic element 220, a larger current than a current of the first electronic element 210 flows, and larger heat is generated. For instance, the second electronic element 220 has been equipped with 4 pieces of power MOS elements 221 to 224 as power elements. These power MOS elements 221 to 224 are controlled by the above-described control elements, and have been arranged as driving elements for driving the drive motors.

The semiconductor device 200 has been equipped with a rectangular-shaped heat sink 230. The heat sink 230 is made of an iron-series metal as an entire structure, for example, pure iron (Fe). Then, the first wiring board 240 and the second wiring board 250 have been mounted on an upper plane of this heat sink 230, while the first and second wiring boards 240 and 250 are separated from each other. As these first and second wiring boards 240 and 250, for instance, ceramics boards having stacked layer structures are employed. These ceramics boards have been fixed on an upper plane of the heat sink 230 by employing, for example, an adhesive agent which owns an electric insulating characteristic, and is made of a resin having a superior heat conduction characteristic. The first wiring board 240 and the second wiring board 250 have been separated from each other in view of a thermal aspect.

Then, the control element functioning as the first electronic element 210 has been mounted on the first wiring board 240, and the power MOS elements 221 to 224 functioning as the second electronic element 220 have been mounted on the second wiring board 250 separated from the first wiring board 240. These first and second electronic elements 210 and 220 have been fixed via, for instance, solder to the first wiring board 240 and the second wiring board 250.

Also, as indicated in FIG. 10A, leads 261 functioning as a plurality of signal terminals have been provided around the control element at an outer peripheral portion of the heat sink 230, whereas leads 262 functioning as a plurality of current terminals have been provided around the power MOS elements 221 to 224. The leads 261 are employed so as to be electronically connected to the microcomputer 211 and the control IC 212, which correspond to the control terminals. The leads 262 are provided so as to be electrically connected to the respective power MOS elements 221 to 224, which correspond to the power elements.

As represented in FIG. 10B, these leads 261 and 262 have been electrically connected to the first electronic element 210 and the second electronic element 220 by being wired by bonding wires 270. It should be understood that the above-explained bonding wires 270 are omitted from FIG. 10A.

Then, connection portions among the first and second electronic elements 210 and 220, the first and second wiring boards 240 and 250, the bonding wires 270, and the bonding wires 270 in the leads 261 and 262; and the heat sink 230 have been molded by employing a resin 280.

In the semiconductor device 200 having the above-explained structure, it is so designed that heat of the second electronic element 220 which radiates larger heat than that of the first electronic element 210 is dissipated via the first and second wiring boards 240 and 250 which are made of the ceramics substrates, and the heat sink 230 to, for example, a housing of a motor.

However, as previously explained, in the case that the heat of the second electronic element 220 is dissipated via the first and second wiring boards 240 and 250, and via the heat sink 230, the below-mentioned difficulties occur, which could be revealed by the consideration of the Inventors of the present invention.

That is, as explained above, the second wiring board 250 has been constituted by the ceramics board made of the ceramics material, whereas the heat sink 230 has been constructed of the metal. As a result, the heat conduction of the second wiring board 250 made of the ceramics board is deteriorated, as compared with the heat conduction of the heat sink 230 made of the metal (Fe). As a result, thermal energy of heat generated from the second electronic element 220 cannot be smoothly transferred from the second wiring board 250 to the heat sink 230.

Also, since the material of the heat sink 230 is different from the material of the second wiring board 250, the second wiring board 250 has been fixed on the heat sink 230 by employing an adhesive agent. As a result, a thermal resistance of a joint portion by the adhesive agent is increased, so that heat cannot be effectively transferred from the second wiring board 250 to the heat sink 230 in an effective manner, and thus, the heat dissipation characteristic is lowered.

Moreover, since the heat sink 230 has been employed so as to dissipate the heat, the size of the semiconductor device 200 becomes large.

Further, electronic apparatus have been proposed in which lead frames, wiring boards for mounting thereon electronic elements, and heat sinks are molded in an integral form by employing resins. FIG. 28 schematically shows a sectional structure of this electronic apparatus as a comparison of the present invention.

The electronic apparatus has been equipped with a wiring board 530a, another wiring board 530b, and leads 550 and 590, which are used to connect the electronic apparatus to an external portion. 4 pieces of power elements 521 to 524 (only, structure of power element 521 is illustrated) for driving a load have been mounted on the wiring board 530a. Various sorts of electronic elements such as a microcomputer 511, a control IC 512, another IC chip 513, and a capacitor 514 have been mounted on the wiring board 530b. The lead 550 has been electrically connected to the wiring board 530b via a bonding wire 516, and the wiring board 530a has been electrically connected to the lead 590 via a bonding wire 516. Also, the wiring board 530a has been electrically connected to the wiring board 530b via another bonding wire (not shown).

The above-explained power elements 521 to 524 are employed so as to drive the load, and a large current flows from these power elements 521 to 524 via the lead 590 to the load. Since the heat generation amounts of these power elements 521 to 524 are large, the wiring boards 530a and 530b are packaged on such a heat sink 540 having a superior heat conductive characteristic, so that heat generated by these power elements 521 to 524 is dissipated.

Also, the lead frames constructed of the leads 550 and 590, the wiring boards 530a and 530b on which the electronic elements 511 to 514 and 521 to 524 have been mounted, and the heat sink 540 have been sealed in an integral manner by employing a mold resin 570.

The above-described electronic apparatus is applied to, for example, a load driving-purpose electronic apparatus which is installed in a space within a door of a vehicle riding purpose, and drives a driving motor of a power window. However, very recently, in vehicles such as automobiles, installation spaces for such an electronic apparatus are gradually narrowed in order to enlarge spaces within vehicles. Therefore, very small sized apparatus have been required.

As a consequence, as to the arrangement for dissipating the heat generated from the power elements 521 to 524 by using such a heat sink 540 shown in FIG. 28, there is a limitation that the electronic apparatus is made compact, resulting in a problem.

### SUMMARY OF THE INVENTION

In view of the above-described problem, it is an object of the present disclosure to provide a semiconductor device having a metallic lead. It is another object of the present disclosure to provide an electronic device having a lead frame.

According to a first aspect of the present disclosure, a semiconductor device includes: first to fourth vertical type semiconductor elements, each of which includes a semiconductor substrate having first and second surfaces, wherein each semiconductor element further includes a first electrode disposed on the first surface of the substrate and a second electrode disposed on the second surface of the substrate, and wherein each semiconductor element is capable of flowing current between the first and second electrodes; a metallic lead for functioning as a wiring and a heat sink; a resin mold for molding the semiconductor elements and a part of the metallic lead; a circuit board; an electric circuit disposed on one side of the circuit board; and an electronic chip disposed on the one side of the circuit board, wherein the electronic chip is capable of driving and controlling each semiconductor element through the electric circuit. The first to fourth semiconductor elements are arranged to be a stack construction in the resin mold. The first to fourth semiconductor elements provide a H-bridge circuit. Each of the first and second electrodes in each semiconductor element is directly connected to the metallic lead so that heat generated in the semiconductor element is radiated through the metallic lead.

In the above device, since each of the first and second electrodes is directly connected to the metallic lead, heat resistance at a connection portion between the semiconductor element and the metallic lead is reduced. Thus, heat radiation of the semiconductor device is improved. Further, since the metallic lead functions as the heat sink, the device includes no heat sink, so that the dimensions of the device are minimized.

According to a second aspect of the present disclosure, an electronic device for driving a load includes: a first lead frame having an element mounting region and an exposing region; a driving element for driving a load and disposed on one side of the element mounting region of the first lead frame; a second lead frame having a contact region, wherein the contact region contacts the driving element in such a manner that the contact region of the second lead frame and the element mounting region of the first lead frame sandwich the driving element; and a resin mold molding the first and second lead frames and the driving element. The exposing region of the first lead frame is exposed from the resin mold.

In the above device, heat generated in the driving element is discharged to the outside through the element mounting region of the first lead frame. Thus, heat radiation of the device is secured sufficiently, so that it is not necessary to form a heat sink on the device. Thus, the dimensions of the device are reduced.

According to a third aspect of the present disclosure, an electronic device for driving a load includes: a lead frame having an element mounting region and an exposing region; a driving element for driving a load and disposed on one side of the element mounting region of the lead frame; a frame member having a contact region, wherein the contact region contacts the driving element in such a manner that the contact region of the frame member and the element mounting region of the lead frame sandwich the driving element; and a resin mold molding the lead frame, the frame member and the driving element. The exposing region of the lead frame is exposed from the resin mold.

In the above device, heat radiation of the device is secured sufficiently, so that it is not necessary to form a heat sink on the device. Thus, the dimensions of the device are reduced.

According to a fourth aspect of the present disclosure, an electronic device for driving a load includes: a lead frame having an element mounting region and an exposing region; a driving element for driving a load and disposed on one side of the element mounting region of the lead frame; and a resin mold molding the lead frame and the driving element. The exposing region of the lead frame is exposed from the resin mold.

In the above device, heat radiation of the device is secured sufficiently, so that it is not necessary to form a heat sink on the device. Thus, the dimensions of the device are reduced.

According to a fifth aspect of the present disclosure, an electronic device for driving a load includes: a first lead frame having an element mounting region and an exposing region; a driving element for driving a load and disposed on one side of the element mounting region of the first lead frame; a second lead frame having a plurality of leads for inputting/outputting an electric signal; and a resin mold molding the element mounting region of the first lead frame, the leads of the second lead frame and the driving element. The exposing region of the first lead frame is exposed from the resin mold.

In the above device, heat radiation of the device is secured sufficiently, so that it is not necessary to form a heat sink on the device. Thus, the dimensions of the device are reduced.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic cross sectional view showing a semiconductor device;

FIGS. 2A to 2C are cross sectional views explaining a method for manufacturing the device shown in FIG. 1;

FIG. 3 is a circuit diagram showing a H bridge circuit in the device shown in FIG. 1;

FIG. 4A is a plan view showing another semiconductor device, and FIG. 4B is a cross sectional view showing the device in FIG. 4A;

FIG. 5 is a schematic view showing arrangement of semiconductor elements in the device shown in FIG. 4A;

FIG. 6 is a schematic cross sectional view showing further another semiconductor device;

FIG. 7 is a top view showing a part of the device seeing from an arrow VII in FIG. 6;

FIG. 8 is a schematic cross sectional view showing another semiconductor device;

FIG. 9 is a schematic cross sectional view showing another semiconductor device;

FIG. 10A is a plan view showing a semiconductor device as a comparison according to a related art, and FIG. 10B is a cross sectional view showing the device taken along line XB-XB in FIG. 10A;

FIG. 11 is a plan view showing another semiconductor device;

FIG. 12 is a cross sectional view showing the device taken along line XII-XII in FIG. 11;

FIG. 13 is a plan view showing a first lead frame in the device shown in FIG. 11;

FIG. 14 is a plan view showing a second lead frame in the device shown in FIG. 11;

FIG. 15 is a circuit diagram showing the device shown in FIG. 11;

FIG. 16A is a schematic view explaining a heat resistance model according to a related art, and FIG. 16B is a schematic view explaining a heat resistance model according to a present embodiment;

FIG. 17 is a plan view showing another semiconductor device;

FIG. 18 is a cross sectional view showing the device taken along line XVIII-XVIII in FIG. 17;

FIG. 19A is a plan view showing another semiconductor device, and FIG. 19B is a cross sectional view showing the device taken along line XIXB-XIXB in FIG. 19A;

FIG. 20A is a plan view showing another semiconductor device, and FIG. 20B is a cross sectional view showing the device taken along line XXB-XXB in FIG. 20A;

FIG. 21 is a partially enlarged view sowing a caulking portion in the device shown in FIG. 20A;

FIG. 22 is a cross sectional view showing the caulking portion taken along line XXII-XXII in FIG. 21;

FIG. 23A is a plan view showing another semiconductor device, and FIG. 23B is a cross sectional view showing the device taken along line XXIIIB-XXIIIB in FIG. 23A;

FIG. 24 is a partially enlarged view sowing a caulking portion in the device shown in FIG. 23A;

FIG. 25 is a cross sectional view showing the caulking portion taken along line XXV-XXV in FIG. 24;

FIG. 26A is a plan view showing another semiconductor device, and FIG. 26B is a cross sectional view showing the device taken along line XXVIB-XXVIB in FIG. 26A;

FIG. 27A is a plan view showing another semiconductor device, and FIG. 27B is a cross sectional view showing the device taken along line XXVIIB-XXVIIB in FIG. 27A; and

FIG. 28 is a cross sectional view showing a semiconductor device according to a related art.

### DETAILED DESCRIPTION OF THE PREFERRED EMBODIMENTS

### First Embodiment

Referring now to drawings, a first embodiment of the present invention will be described. A semiconductor device indicated in this first embodiment is applied to an HIC (Hybrid Integrated Circuit) which drives a driving motor of a power window.

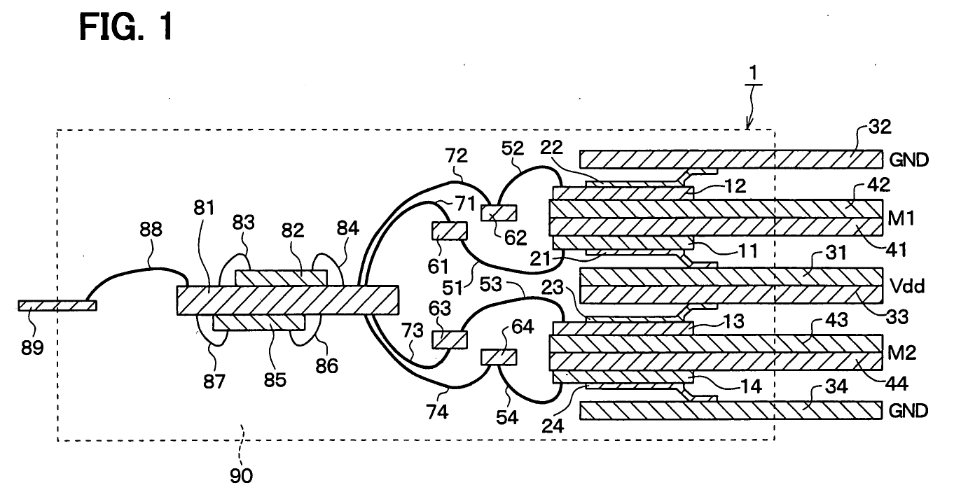

FIG. 1 is a sectional view for schematically showing a semiconductor device 1 according to the first embodiment of the present invention. As shown in this drawing, the semiconductor device 1 has been equipped with a first semiconductor element 11 to a fourth semiconductor element 14. Each of the first to fourth semiconductor elements 11 to 14 has a rectangular shape, and has been made by that a power element having a MOS structure is formed on a semiconductor substrate, for example, a silicon semiconductor, while a heat generation amount of the power element is large.

Concretely speaking, P-ch (P channel) type DMOS elements have been formed in the first and third semiconductor elements 11 and 13, and N-ch (N channel) type DMOS elements have been formed in the second and fourth semiconductor elements 12 and 14 among the first to fourth semiconductor elements 11 to 14. These first to fourth semiconductor elements 11 to 14 have been electrically connected to each other in order to constitute an H bridge circuit.

It should be understood that a P-ch type DMOS element corresponds to such a type DMOS element that when a gate voltage is lower than a source voltage, a current flows, whereas an N-ch type DMOS element corresponds to such a type DMOS element that when a gate voltage is higher than a source voltage, a current flows.

Ribbon leads 21 to 24 have been joined to source pads (namely, first electrode) by way of, for example, solder, while these source pads (not shown) have been provided with these first to fourth semiconductor elements 11 to 14. These ribbon leads 21 to 24 have been made of such a metal plate having a superior heat conductivity characteristic, for example, Al (i.e., aluminum). The metal plate having a thickness of, for example, approximately 0.1 mm has been employed.

Then, portions of the respective ribbon leads 21 to 24 have been joined to the respective source pads of the first to fourth semiconductor elements 11 to 14, whereas portions of such portions of the ribbon leads 21 to 24, which are not joined to the respective source pads have been joined to leads 31 to 34 respectively. These leads 31 to 34 have been made of such a metal plate having a superior heat conductivity characteristic such as Cu (i.e., copper). This metal plate having a thickness of 0.3 to 1.0 mm has been employed.

Also, drain pads (namely, second electrodes) have been provided on planes of the respective semiconductor elements 11 to 14, which are located opposite to the planes thereof where the source pads have been provided. Leads 41 to 44 have been joined to these drain pads (not shown).

Planes of these leads 41 and 42 connected to the respective drain pads of the first and second semiconductor elements 11 and 12, which are located opposite to the planes to which the respective semiconductor elements 11 and 12 have been joined, have been pasted to each other to be brought into a close fitted condition. Concretely speaking, while a concave portion has been formed in one plane of the planes to be pasted with each other in the respective leads 41 and 42 and a convex portion has been formed on the other plane in correspondence with the concave portion, when these leads 41 and 42 are pasted to each other, the convex portion provided on the other plane is engaged with the concave portion provided on one plane. As previously explained, since the concave/convex shapes are formed on the respective surfaces of the leads 41 and 42 which are pasted to each other, these leads 41 and 42 can be closely contacted to each other when the respective leads 41 and 42 are pasted to each other.

Similarly, planes of these leads 31 and 33 electrically connected to the respective source pads of the first and third semiconductor elements 11 and 13 via the ribbon pads 21 and 23, which are located opposite to the planes to which the ribbon leads 21 and 23 have been joined, have been pasted to each other. Furthermore, planes of the leads 43 and 44 connected to the respective drain pads of the third and fourth semiconductor elements 13 and 14, to which the respective semiconductor elements 13 and 14 are joined, have been pasted to the planes located opposite thereto. As previously explained, since the concave/convex portions are formed on the respective leads 31, 33, 43, and 44, which are pasted to each other, these leads 31, 33, 43 and 44 can be closely contacted to each other when the respective leads 31, 33, 43, and 44 pasted to each other.

In this first embodiment, the leads 32 and 34 are assumed as GND (ground) terminals respectively, which have been electrically connected via the ribbon leads 22 and 24 to the source pads of the second and fourth semiconductor elements 12 and 14 respectively. Also, the respective leads 41 and 42 joined via the respective drain pads of the first and second semiconductor elements 11 and 12 are defined as M1 terminals, whereas the respective leads 43 and 44 joined via the respective drain pads of the third and fourth semiconductor elements 13 and 14 are defined as M2 terminals. Then, the respective leads 31 and 33 are defined as a “Vdd” terminal, which have been electrically connected to the respective drain pads of the first and third semiconductor elements 11 and 13 via the ribbon leads 21 and 23.

As previously explained, the ribbon leads 21 to 24, the leads 31 to 34 and the leads 41 to 44 which have been electrically connected to the respective semiconductor elements 11 to 14 are constructed of the above-described metal plates having the superior heat conductivity characteristic, namely superior heat dissipation characteristic, so that these ribbon leads 21 to 24, leads 31 to 34 and leads 41 to 44 may play a role of a heat sink capable of dissipating heat generated from the respective semiconductor elements 11 to 14 to an external portion.

As a consequence, the respective ribbon leads 21 to 24 have been joined to the respective source pads of the first to fourth semiconductor elements 11 to 14, the respective ribbon leads 21 to 24 have been joined to the respective leads 31 to 34, and the respective leads 41 to 44 have been jointed to the respective drain pads of the first to fourth semiconductor elements 11 to 14, so that heat generated from the respective semiconductor elements 11 to 14 can be directly dissipated from both planes of each of the source pads and each of the drain pads via the ribbon leads 21 to 24, and the leads 31 to 34, and 41 to 44 to the external portion.

Also, the gate pads (not shown) have been provided on the same planes in each of the first to fourth semiconductor elements 11 to 14, as the planes where the source pads have been provided. While wires 51 to 54 have been joined to the respective gate pads of the respective first to fourth semiconductor elements 11 to 14, these wires 51 to 54 have been connected to relay leads 61 to 64, respectively. Furthermore, wires 71 to 74 have been connected to the respective relay leads 61 to 64, the respective 71 to 74 have been electrically connected to a stacked layer substrate 81 respectively.

The above-explained stacked layer substrate 81 has been constructed of a stacked layer structure, and has been arranged by equipping an electric circuit within an internal portion thereof. A driving-purpose chip 82 for driving the above-explained first to fourth semiconductor elements 11 to 14 has been provided on this stacked layer substrate 81. The driving-purpose chip 82 has been electrically connected via wires 83 and 84 to the electric circuit employed in the stacked layer substrate 81. It should also be understood that the stacked layer substrate 81 has been brought into such a condition that this stacked layer substrate 81 is mounted on a frame (not shown).

Also, microcomputer chip 85 for controlling and driving the driving-purpose chip 82 has been set on a plane of the stacked layer substrate 81, which is located opposite to a plane where the driving-purpose chip 82 is set. This microcomputer chip 85 has been electrically connected to the electric circuit employed in the stacked layer substrate 81 via wires 86 and 87. The above-explained driving-purpose chip 82 and microcomputer chip 85 have been mounted on the stacked layer substrate 81 by way of, for example, Ag paste.

Moreover, the electric circuit provided in the stacked layer substrate 81 has been electrically connected via a wire 88 to a lead 89. As a result, a signal derived from the external portion may be inputted via the electric circuit employed in the stacked layer substrate 81 to both the microcomputer chip 85 and the driving-purpose chip 82. It should also be noted that a plurality of leads 89 have been arranged along a vertical direction of a paper plane.

In this first embodiment, as the above-explained wires 51 to 54, 71 to 74, 83, 84, and 86 to 88, for example, Au wires are employed.

Then, the stacked layer substrate 81, the relay leads 61 to 64, and the respective first to fourth semiconductor elements 11 to 14 have been molded by a resin 90 in such a manner that edge portions of the respective leads 31 to 34, 41 to 44, and 89 are exposed. In FIG. 1, an outer wall potion of the resin 90 is indicated by a broken line, and this resin 90 has been filled into an internal portion of this broken line. The above-explained structure is the structure of the semiconductor device 1 according to this first embodiment.

It should also be noted that the leads 31 to 34, 41 to 44, and the ribbon leads 21 to 24, according to this first embodiment, correspond to metal leads, and furthermore, the leads 31 to 34, and 41 to 44 correspond to plate-shaped leads. Also, both the driving-purpose chip 82 and the microcomputer chip 85 correspond to electronic elements. Furthermore, the Ml terminal and the M2 terminal correspond to a first load connecting-purpose terminal and a second load connecting-purpose terminal. The Vdd terminal corresponds to a power supply terminal, and the GND terminal corresponds to a ground-purpose terminal.

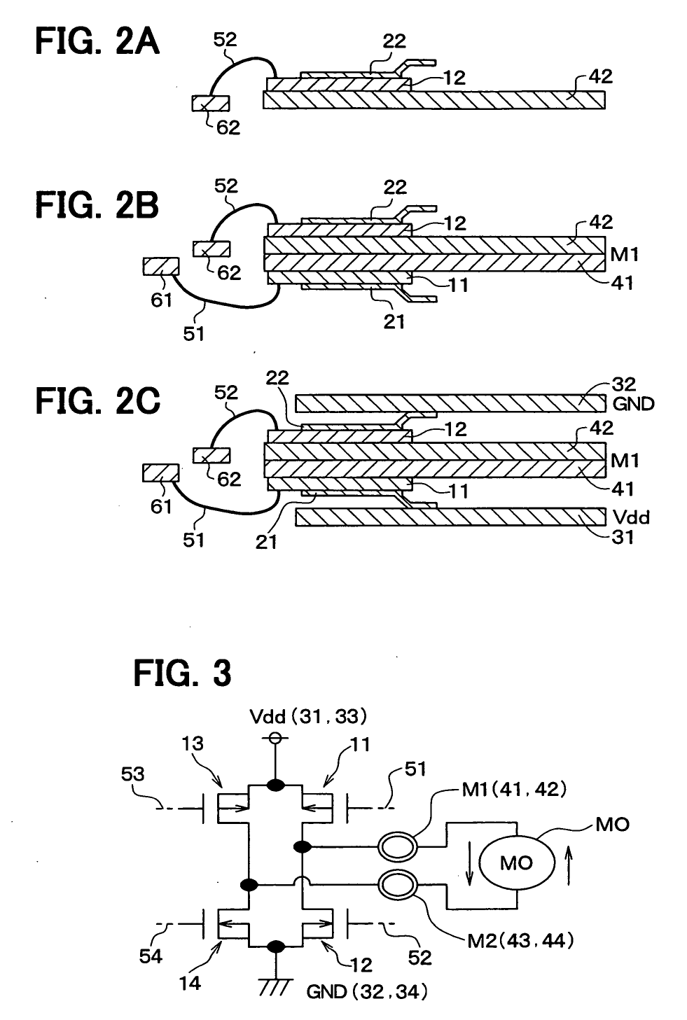

Subsequently, a description is made of a method for manufacturing the above-explained semiconductor device 1 with reference to drawings. FIG. 2A to FIG. 2C are diagrams for indicating manufacturing steps of the semiconductor device 1 shown in FIG. 1.

Firstly, a frame (not shown) is prepared in which the relay lead 62 has been connected to the lead 42 by an external die bar. Then, in the step shown in FIG. 2A, the second semiconductor element 12 is joined to the lead 42 by way of solder. Concretely speaking, while a concave has been previously formed in a predetermined portion of the lead 42, the drain pad of the second semiconductor element 12 is soldered to this concave.

It should also be noted that since the surface of the lead 42 has been plated by way of a Ni plating method, the semiconductor element 12 may be easily soldered to the lead 42. Also, for example, such a metal plate made of Cu and having a thickness of 0.3 to 1.0 mm is employed as the lead 42.

Thereafter, the gate pad of the second semiconductor element 12 is wire-bonded to the relay lead 62 by employing the wire 52 by a bonding apparatus, and the ribbon lead 22 is soldered on the source pad of the second semiconductor element 12. As previously explained, such a metal plate which is made of Al and has a thickness smaller than, or equal to 0.1 mm is employed as the ribbon lead 22.

Then, such a resulting semiconductor device as shown in FIG. 2A is prepared for each of the first to fourth semiconductor elements 11 to 14.

In the step shown in FIG. 2B, an M1 terminal is constructed. In other words, the lead 41 joined to the first semiconductor element 11 is pasted to the lead 42 joined to the second semiconductor element 12. Concretely speaking, the planes of the leads 41 and 42 are pasted to each other, which are located opposite to the planes of these leads 41 and 42, to which the first and second semiconductor devices 11 and 12 have been joined.

In this case, a concave and a convex have been previously formed in the planes of the leads 41 and 42, which are located opposite to the planes of these leads 41 and 42, to which the first and second semiconductor devices 11 and 12 have been joined, so that the respective leads 41 and 42 may be closely contacted to each other. The M1 terminal is constructed in the above-explained manner. Similarly, also in the third semiconductor element 13 and the fourth semiconductor element 14, the respective leads 43 and 44 are pasted to each other in order to construct an M2 terminal.

In a step shown in FIG. 2C, both a GND terminal and a Vdd terminal are constructed. Concretely speaking, the semiconductor device shown in FIG. 2B which has been formed by employing the first semiconductor element 11 and the second semiconductor element 12 is fixed by a spacer jig so as to determined, for example, a positional relationship between the respective leads 41, 42, and the respective leads 31, 32, and the leads 31 and 32 are joined to the respective ribbon leads 21 and 22 by a soldering manner, or a welding manner. As a result, both the GND terminal and the Vdd terminal can be formed.

Similarly, such a semiconductor device shown in FIG. 2B is prepared which has been formed by employing the third semiconductor element 13 and the fourth semiconductor element 14, and the respective leads 33 and 34 are joined to the respective ribbon leads 23 and 24 so as to form such a semiconductor device as shown in FIG. 2C.

Thereafter, although not shown in the drawing, the lead 31 electrically connected via the ribbon lead 21 to the first semiconductor element 11 as a Vdd terminal is pasted to the lead 33 electrically connected via the ribbon lead 23 to the third semiconductor element 13 as another Vdd terminal in such a manner that the planes of these leads 31 and 33 are located opposite to the planes to which the ribbon leads 21 and 23 are joined. As a result, a single Vdd terminal is constructed. As previously explained, such an H bridge circuit portion shown in FIG. 1 is accomplished.

Then, while such a semiconductor device is prepared in which the driving-purpose chip 82 and the microcomputer chip 85 have been mounted on the stacked layer substrate 81 and have been wire-bounded thereon, a positional relationship between the H bridge circuit portion and the stacked layer substrate 81 is fixed by a jig of the wire bonding apparatus so as to the determined. Thereafter, the respective relay leads 61 to 64 are wire-bonded to the electric circuit employed in the stacked layer substrate 81 by employing the respective wires 71 to 74. As explained above, the H bridge circuit portion can be electrically connected to the stacked layer substrate 81 via the relay leads 61 to 64 and the wires 51 to 54, 71 to 74.

Next, the lead 89 used to input a signal from an external unit is wire-bonded to the electric circuit provided in the stacked layer substrate 81 by using the wire 88, and the stacked layer substrate 81, the relay leads 61 to 64, and the H bridge circuit portion are molded by way of the resin 90 in such a manner that the edge portions of the leads 31 to 34, 41 to 44, and 89 are exposed from the resin 90. Thus, the semiconductor device 1 as shown in FIG. 1 is accomplished.

In the arrangement of the above-explained semiconductor device 1, a description is made of such a circuit which is constituted by the first to fourth semiconductor devices 11 to 14. FIG. 3 represents a circuit diagram as to the H bridge circuit portion constructed of the first to fourth semiconductor devices 11 to 14.

As indicated in FIG. 3, the respective semiconductor elements 11 to 14 have constituted the H bridge circuit. Also, in this semiconductor device 1, the above-explained motor MO for driving window glass of a vehicle, and a power supply of an apparatus (not shown).

In the H bridge circuit, a Vdd voltage is applied to the respective sources of the P-ch type first and third semiconductor elements 11 and 13. Also, the motor MO for opening and closing the window glass of the vehicle has been connected between the M1 terminal and the M2 terminal, while the M1 terminal is arranged by the respective drains of the first and second semiconductor elements 11 and 12, and the M2 terminal is arranged by the respective drains of the third and fourth semiconductor elements 13 and 14. Then, the GND voltage is inputted to the respective sources of the N-ch type second and fourth semiconductor elements 12 and 14.

In the above-explained circuit arrangement, the motor MO can be driven in accordance with the below-mentioned manner. First of all, in each of the first to fourth semiconductor elements 11 to 14, since a current is inputted to the gate thereof, a current may flow between the source and the drain. As a consequence, signals are inputted via the respective wires 51 to 54 to the respective gates of the respective semiconductor elements 11 to 14, so that the respective semiconductor elements 11 to 14 are driven, and eventually, the motor MO is driven.

Concretely speaking, a signal is entered to the microcomputer chip 85 via the lead 89, the wire 88, and the electric circuit employed in the stacked layer substrate 81 by a communication from an external microcomputer (not shown). In response to the inputted signal, the microcomputer chip 85 controls the respective semiconductor elements 11 to 14 via the electric circuit provided in the stacked layer substrate 81 and the driving-purpose chip 82. The driving-purpose chip 82 inputs signals to the gates of the respective semiconductor elements 11 to 14 via the electric circuit employed in the stacked layer substrate 81, the relay leads 61 to 64, and the wires 51 to 54, 71 to 74.

Then, a driving device for causing the window glass of the vehicle to ascend and descend is the motor MO. This motor MO has been set to a mechanism which is known in the technical field and causes window glass installed in an inner ornament of a door.

When the motor MO is stopped, all of the first to fourth semiconductor elements 11 to 14 are brought into OFF statuses. When the window glass ascends, a current is entered from the driving-purpose chip 82 to, for example, respective gates of two semiconductor elements 11 and 14 so as to be brought into ON statuses, which are positioned on one diagonal in the H bridge circuit. Thus, the current flows through the first semiconductor element 11, the motor MO, and the fourth semiconductor element 14 in this order, so that the motor MO is rotated. At this time, the current is not inputted to the respective gates of two semiconductor elements 12 and 13, which are located on the other diagonal, so that these semiconductor elements 12 and 13 are brought into the OFF statuses.

Also, when the window glass descends, two pieces of the semiconductor elements 11 and 14 which are located on one diagonal in the H bridge circuit are brought into OFF statuses. On the other hand, a current is entered from the driving-purpose chip 82 to, for example, respective gates at two semiconductor elements 12 and 13 so as to be brought into ON statuses, which are positioned on the other diagonal in the H bridge circuit. Thus, the current flows through the third semiconductor element 13, the motor MO, and the second semiconductor element 12 in this order, so that the motor MO is rotated.

In other words, when the window glass ascends and descends, the direction of the current flowing to the motor MO is reversed by the H bridge circuit, and therefore, the rotation of the motor MO is also reversed in response to this action. As previously explained, since the direction of the current flowing into the motor MO is controlled by the H bridge circuit, the window glass of the vehicle can be opened and closed.

As previously explained, when the motor MO is driven by the respective semiconductor elements 11 to 14, the large currents flow through the respective semiconductor elements 11 to 14, so that heat is generated. This generated heat is dissipated to the external unit via the leads 41 to 44 joined to the respective drain pads of the first to fourth semiconductors 11 to 14, the ribbon leads 21 to 24 joined to the source pads, and the respective leads 31 to 34 joined to the respective ribbon leads 21 to 24. As previously explained, since the leads 31 to 34, the leads 41 to 44, and the ribbon leads 21 to 24 also play the role of the heat sink, the heat dissipation can be realized.

More specifically, in the respective leads 41 to 44 which constitute the M1 terminal and the M2 terminal, heat generated from the respective semiconductor elements 11 to 14 can be directly dissipated via the respective leads 41 to 44 to, for example, a bus bar (not shown) coupled to the housing of the motor MO. In this first embodiment, the respective semiconductor elements 11 to 14 are directly joined to the respective leads 41 to 44 by way of the solder without employing an adhesive agent, so that the thermal resistances can be reduced, and thus, the heat dissipation characteristics as to these first to fourth semiconductor elements 11 to 14 can be improved.

Similarly, the respective ribbon leads 21 to 24 are directly joined to the respective source pads of the respective semiconductor elements 11 to 14, so that the thermal resistances between the respective semiconductor elements 11 to 14 and the ribbon leads 21 to 24 can be reduced, and thus, the heat dissipation characteristics can be improved.

It should also be understood that although a heat sink used for the driving-purpose chip 82 and the microcomputer chip 85 is not employed in this first embodiment, heat generated in the driving-purpose chip 82 and heat generated in the microcomputer chip 85 are dissipated to the stacked layer substrate 81. As a consequence, even when such a heat sink for dissipating the heat of the driving-purpose chip 82 and the microcomputer chip 85 is not provided in the semiconductor device 1, there is no problem.

As previously explained, this first embodiment is featured by that the leads 41 to 44 and the ribbon leads 21 to 24 which play the role of the heat sink are directly joined to both the upper planes and the lower planes of the respective semiconductor elements 11 to 14, namely joined to the respective planes where the source pads and the drain pads have been provided. As a result, the thermal resistance of the join portions between the respective semiconductor elements 11 to 14 and the leads 41 to 44, and the thermal resistance of the join portions between the respective semiconductor elements 11 to 14 and the ribbon leads 21 to 24 can be reduced. As a consequence, the thermal energy between the respective semiconductor elements 11 to 14 and the leads 41 to 44, and also, the thermal energy between the respective semiconductor elements 11 to 14 and the ribbon leads 21 to 24 can be smoothly transferred, so that heat can be conducted via the leads 31 to 34, 41 to 44, and the ribbon leads 21 to 24 outside the resin 90. The heat dissipation characteristics of the respective semiconductor elements 11 to 14 can be improved in the above-described manner.

As previously explained, even when the semiconductor device 1 is not equipped with the heat sink, the leads 31 to 34, 41 to 44 (and also ribbons 21 to 24) functioning as the wiring lines are employed as the heat sinks, so that the heat dissipation characteristics of the power elements having the large heat generation amounts can be secured.

Also, in the semiconductor device 1, the heat generated from the respective semiconductor elements 11 to 14 can be dissipated outside this semiconductor device 1 without employing the heat sink, so that the dimension of the semiconductor device 1 can be made compact. As indicated in FIG. 1, in this first embodiment, the respective semiconductor elements 11 to 14, and the leads 31 to 34, and 41 to 44 are arranged in the multiple stages. As a result, the area of the semiconductor device 1, as viewed from the plan view, can be decreased, and eventually, the semiconductor device 1 can be made compact.

Also, as explained in this first embodiment, since the semiconductor device 1 is arranged without employing the heat sink for the heat dissipation purpose, the manufacturing cost and the manufacturing steps as to the semiconductor device 1 can be reduced.

### Second Embodiment

In a second embodiment of the present invention, only different portion from that of the first embodiment will be explained. That is, in this second embodiment, such an arrangement is different from that of the first embodiment, namely, respective leads 31 to 34, 41 to 44, and 89 are arranged in an in-line type on the same plane.

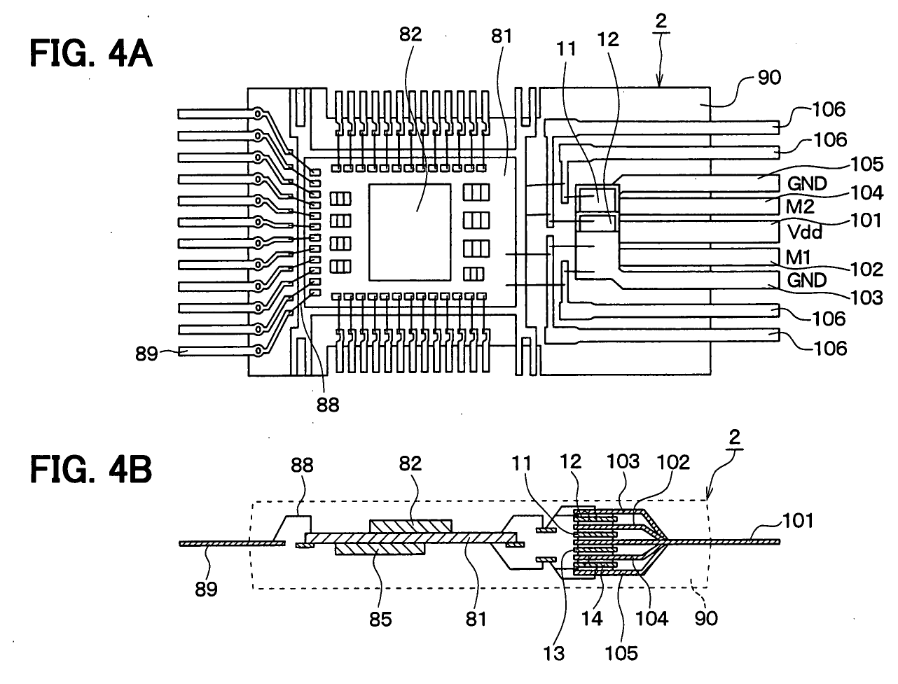

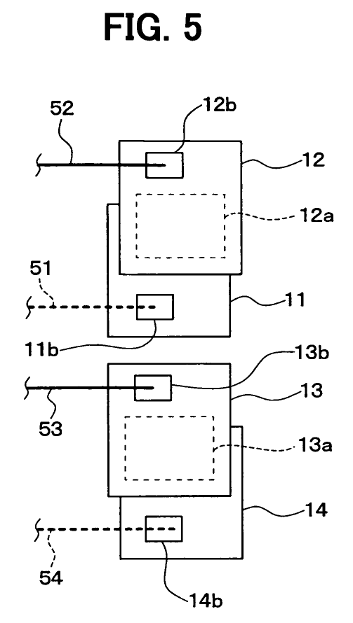

FIG. 4A and FIG. 4B are diagrams for indicating a semiconductor device 2 according to this second embodiment. That is, FIG. 4A is a plan view for indicating the semiconductor device 2, and FIG. 4B is a sectional view for schematically indicating the semiconductor device 2. Also, FIG. 5 schematically represents an arrangement of the respective semiconductor elements 11 to 14 in FIG. 4A. It should be noted that in FIG. 5, the respective leads 101 to 106 are omitted. Also, in FIG. 4B, an outer wall portion of the resin 90 is indicated by a broken line, and the resin 90 has been filled inside the broken line.

As indicated in FIG. 4A, in this second embodiment, a GND terminal, an M1 terminal, an M2 terminal, and a Vdd terminal, namely the respective leads 101 to 106 have been arranged on the same plane. As indicated in FIG. 4B, the respective leads 101 to 106 have been bending-processed within a mold package. As a consequence, edge portions of the respective leads 101 to 106 which are exposed from the resin 90 are arranged on the same plane.

Concretely speaking, as shown in FIG. 4B and FIG. 5, a source pad of a first semiconductor element 11 has been joined to the lead 101 functioning as the Vdd terminal. Also, in the lead 101, a source pad 13a of a third semiconductor element 13 has been joined to a plane thereof which is located opposite to another plane to which the first semiconductor element 11 has been joined.

The leads 102 functioning as the M1 terminal has been joined to a drain pad of the first semiconductor element 11, and a drain pad of the second semiconductor element 12 has been joined to a plane of the lead 102, which is located opposite to another plane thereof to which the first semiconductor element 11 has been joined. In this lead 102, such a side portion has been bending-processed in order that the lead 101 does not constitute the multi-staged structure with respect to the lead 102 functioning as the Vdd terminal, which is located opposite to another side portion thereof to which the first and second semiconductor elements 11 and 12 have been joined.

Then, the lead 103 functioning as the GND terminal has been joined to a source pad 12a of the second semiconductor element 12. Also, the lead 103 has been bending-processed in order that this lead 103 does not constitute the multi-staged structure with respect to the leads 101 and 102.

Similarly, the lead 104 functioning as the M2 terminal has been joined to a drain pad of the third semiconductor element 13, and a drain pad of the fourth semiconductor element 14 has been joined to a plane of the lead 104, which is located opposite to another plane thereof to which the second semiconductor element 13 has been joined. Then, the lead 105 functioning as the GND terminal has been joined to a source pad of the fourth semiconductor element 14. Similar to the above case, in these leads 104 and 105, such side portions have been bending-processed in order that the leads 104 and 105 do not constitute the multi-staged structures with respect to the lead 101 functioning as the Vdd terminal, which is located opposite to other side portions thereof to which the third and fourth semiconductor element 13 and 14 have been joined.

Furthermore, the leads 102 to 105 have been bending-processed within the mold package in order that the edge portions of the leads 102 to 105 are arranged within the same plane as the lead 101. As a result, the portions of the respective leads 101 to 106 which are exposed from the resin 90 are arranged on the same plane. Also, when the respective leads 102 to 105 are bending-processed on the above-explained manner, these leads 102 to 105 have been extracted from the respective semiconductor chips 11 to 14 in order that these leads 101 to 105 are not overlapped with each other, and then, have been extended up to the external portion of the resin 90.

Also, wires 51 to 54 have been joined to gate pads 11b to 14b of the respective semiconductor elements 11 to 14. In this second embodiment, as represented in FIG. 5, the respective semiconductor elements 11 to 14 have been arranged in such a way that these semiconductor elements 11 to 14 are moved along such a direction perpendicular to the longitudinal directions of the respective leads 101 to 105. As a consequence, the wires 51 to 54 can be easily extended from the respective gate pads 11b to 14b of the respective semiconductor elements 11 to 14.

It should also be noted that a lead 106 is used as a position detecting-purpose terminal which detects a position of window glass driven by the motor MO connected to the M1 terminal and the M2 terminal.

As explained above, even when the respective leads 101 to 105 are arranged on the same plane by shifting the arrangement of the respective semiconductor elements 11 to 14, and by bending the respective leads 102 to 105, there is no problem. As a result, the semiconductor device 2 may be alternatively formed in such a mode that this semiconductor device 2 may be readily connected to the external portion.

### Third Embodiment

In a third embodiment of the present invention, only different portion from that of the above-explained embodiments will be explained. That is, in this third embodiment, such an arrangement is different from that of the above-described embodiments, namely, shapes of respective leads functioning as a Vdd terminal and a GND terminal, which are joined to the respective semiconductor elements 11 to 14, are different from those of the first and second embodiments.

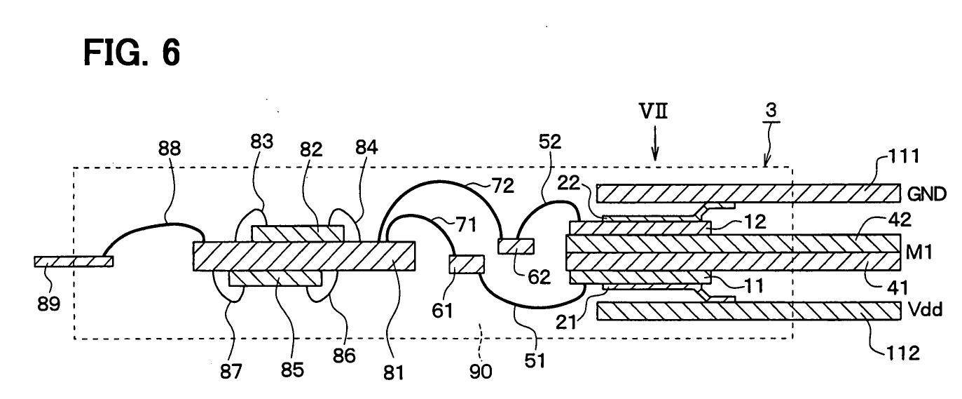

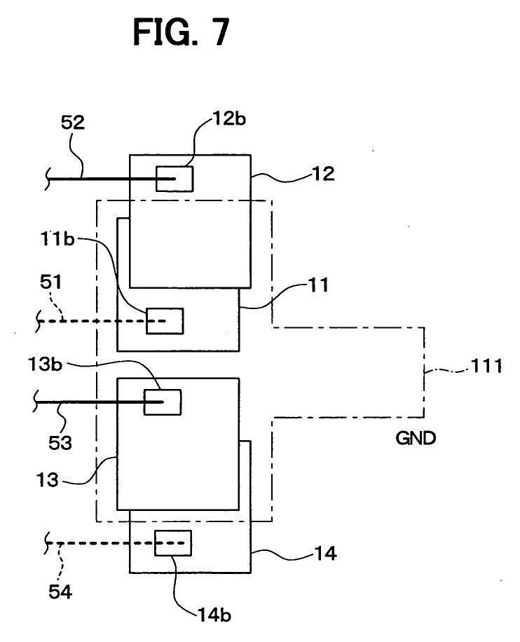

FIG. 6 is a sectional view for schematically showing a semiconductor device 3 according to this third embodiment. FIG. 7 is a view for indicating the semiconductor device 3, as viewed along an arrow “VII” of FIG. 6. It should be noted that an outer wall portion of the resin 90 is indicated by a broke line, and the resin 90 has been filled inside the broken line in FIG. 6. Also, in FIG. 7, since ribbon leads 22 and 24, M1 and M2 terminals (leads 41 to 44), and a Vdd terminal (lead 112) are omitted, only a lead 111 functioning as a GND terminal is illustrated.

As shown in FIG. 6, in the semiconductor device 3 according to this third embodiment, respective semiconductor elements 11 to 14 have been arranged along a vertical direction, as viewed on a paper plane, namely, along a direction perpendicular to the longitudinal direction of the leads 41 and 42 functioning as the M1 terminal. Although only the first and second semiconductor elements 11 and 12 are illustrated in FIG. 6, as previously explained, the third and fourth semiconductor elements 13 and 14 (not shown) have been arranged along the vertical direction, as viewed on the paper plane. Such an arrangement may be realized by employing a GND terminal which is commonly used for the second and fourth semiconductor elements 12 and 14, and a Vdd terminal which is commonly used for the first and third semiconductor elements 11 and 13.

Concretely speaking, as represented in FIG. 7, the lead 111 has been made in a T-shaped form which is constituted by a straight line portion where the second and fourth semiconductor elements 12 and 14 are connected along the longitudinal direction, and by another straight line portion arranged perpendicular to the first-mentioned straight line portion. Similarly, the lead 112 has been made in a T-shaped form which is constituted by a straight line portion where the first and third semiconductor elements 11 and 13 are connected along the longitudinal direction, and by another straight line portion arranged perpendicular to the first-mentioned straight line portion.

Then, as indicated in FIG. 6 and FIG. 7, with respect to the lead 111 functioning as the GND terminal, the respective source pads of the second and fourth semiconductor elements 12 and 14 have been connected via the ribbon leads 22 and 24. Also, with respect to the lead 112 functioning as the Vdd terminal having the same T-shaped form as that of the GND terminal, the respective source pads of the first and third semiconductor elements 11 and 13 have been connected via the ribbon leads 21 and 23.

Furthermore, as shown in FIG. 6, the M1 terminal has been arranged by employing the respective leads 41 and 42 which are joined to the respective drain pads of the first and second semiconductor elements 11 and 12. Then, although not shown in the drawing, the M2 terminal has been arranged by employing the respective leads 43 and 44 which are joined to the respective drain pads of the third and fourth semiconductor elements 13 and 14.

Similar to the above-explained embodiments, the wires 51 to 54 have been connected to the respective gate pads 11b to 14b of the respective semiconductor elements 11 to 14.

As explained above, since the leads 111 and 112 functioning as the GND terminal and the Vdd terminal are formed in the T-shaped shapes, there is no problem even when the leads 111 and 112 may be commonly used. As a result, a total number of used leads can be reduced, and the leads 41 to 44, 111, and 112 can be readily assembled with respect to the respective semiconductor elements 11 to 14.

### Fourth Embodiment

In a fourth embodiment of the present invention, only different portion from that of the above-explained embodiments will be explained. That is, in this fourth embodiment, such an arrangement is different from that of the above-described embodiments, namely, leads 41 and 42 functioning as an M1 terminal, leads 43 and 44 functioning as an M2 terminal, and leads 31 and 33 functioning as a Vdd terminal are constituted by employing a single lead, respectively.

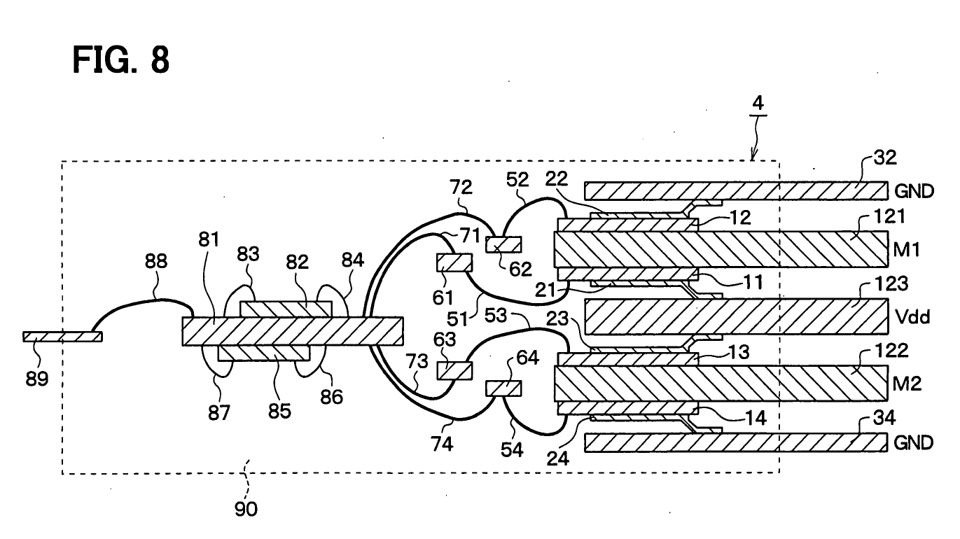

FIG. 8 is a sectional view for schematically showing a semiconductor device 4 according to this fourth embodiment. It should be noted that an outer wall portion of the resin 90 is indicated by a broken line, and the resin 90 has been filled inside the broken line in FIG. 8.

As indicated in FIG. 8, in the semiconductor device 4 according to this fourth embodiment, in an H bridge circuit portion, a lead 121 functioning as the M1 terminal has been jointed to the drain pad of the second semiconductor element 12. Then, in the lead 121, the drain pad of the first semiconductor element 11 has been joined to a plane thereof, which is located opposite to another plane thereof to which the second semiconductor element 12 has been joined.

Similarly, another lead 122 functioning as the M2 terminal has been jointed to the drain pad of the fourth semiconductor element 14. Then, in the lead 122, the drain pad of the third semiconductor element 13 has been joined to a plane thereof, which is located opposite to another plane thereof to which the fourth semiconductor element 14 has been joined. Also, another lead 123 functioning as the Vdd terminal has been connected via the ribbon leads 21 and 23 to the respective source pads of the first and third semiconductor elements 11 and 13, respectively.

As previously explained, since the M1 terminal, the M2 terminal, and the Vdd terminal may be arranged by employing the commonly used leads 121 to 123, there is no problem even when the structures of the leads 121 to 123 are made simpler. As a result, the M1 terminal, the M2 terminal, and the Vdd terminal can be commonly used, and the structure of the semiconductor device 4 can be made similar.

### Fifth Embodiment

In a fifth embodiment of the present invention, only different portion from that of the above-described embodiments will be explained. That is, in this fifth embodiment, such an arrangement is different from that of the above-explained embodiments, namely, while the ribbon leads 21 to 24 are not employed, the GND terminal, the M1 terminal, the M2 terminal, and the Vdd terminal have been joined to the respective semiconductor elements 11 to 14. Also, the respective gate pads of the first and third semiconductor elements 11 and 13 have been connected to the respective relay leads 61 and 63 by employing ribbon leads.

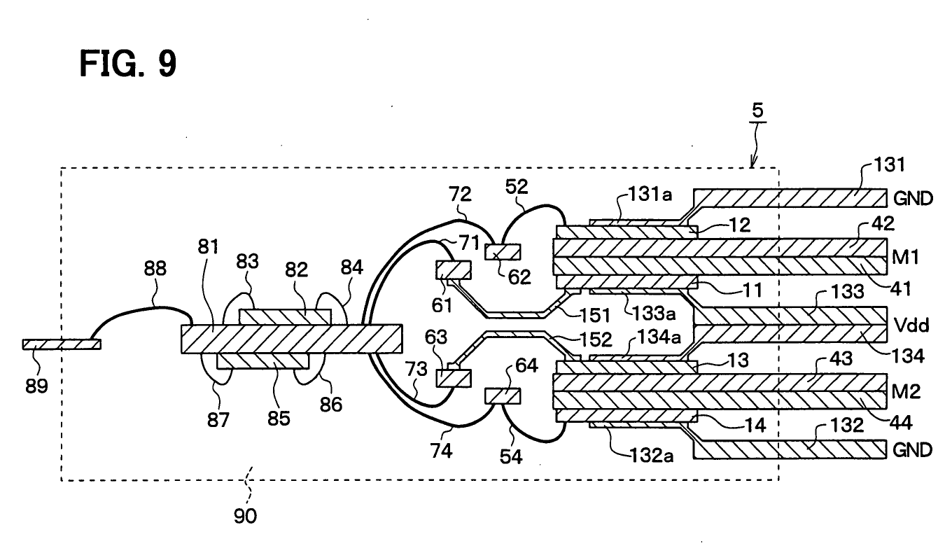

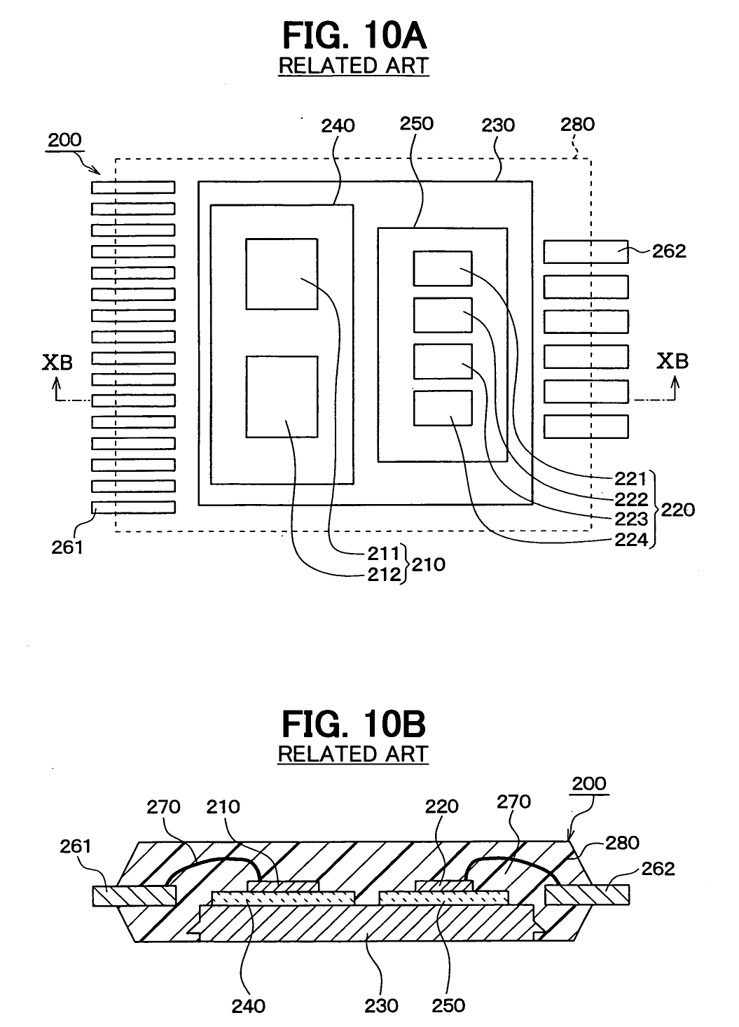

FIG. 9 is a sectional view for schematically showing a semiconductor device 5 according to this fifth embodiment. It should be noted that an outer wall portion of the resin 90 is indicated by a broken line in FIG. 9, and the resin 90 has been filled inside the broken line.

As shown in FIG. 9, in the semiconductor device 5 according to this fifth embodiment, one ends of leads 131 and 132 have been joined to the respective source pads of the second and fourth semiconductor elements 12 and 14 respectively. These one ends of leads 131 and 132 have been made as such ribbon lead portions 131a and 132a that one end of a metal plate has been drawn out as a thinner plate by rolling this metal plate and has been bending-processed, which is like a ribbon lead. In other words, the respective ribbon lead portions 131a and 132a of the respective leads 131 and 132 have been directly joined to the respective source pads of the second and fourth semiconductor elements 12 and 14. Also, other ends of the respective leads 131 and 132 have been exposed from the resin 90 as GND terminals, respectively.

Similarly, the respective ribbon lead portions 133a and 134a of the respective leads 133 and 134 have been directly joined to the respective source pads of the first and third semiconductor elements 11 and 13. These leads 133 and 134 have similar shapes as those of the respective leads 131 and 132. Then, other ends of the respective leads 133 and 134 are pasted to each other, and the pasted other ends are exposed from the resin 90 as the Vdd terminal.

Also, the respective gate pads of the first and third semiconductor elements 11 and 13 have been connected to the relay leads 61 and 62 by ribbon leads 151 and 152. As a result, when the leads 133 and 134 are joined to the first and third semiconductor elements 11 and 13 respectively, the above-explained ribbon leads 151 and 152 can be connected between the respective gate pads and the relay leads 61 and 62. As a consequence, since the second and fourth semiconductor elements 12 and 14 may be merely wire-bonded to the respective relay leads 62 and 64, the semiconductor device 5 may be readily manufactured.

As previously explained, the respective ribbon lead portions 131a to 134a of the respective leads 131 to 134 may be directly joined to the respective source pads of the respective semiconductor elements 11 to 14. As a consequence, heat generated in the respective semiconductor elements 11 to 14 can be dissipated via the leads 41 to 44, and 131 to 134, which have been directly joined to the respective semiconductor elements 11 to 14.

It should also be noted that the leads 131 to 134 employed in this fifth embodiment correspond to processed leads.

### Modifications

While the structures and the modes indicated in the above-described respective embodiments merely indicate one example, the contents shown in the respective embodiments may be alternatively combined with each other.

In the above-described respective embodiments, the respective semiconductor elements 11 to 14 have been electrically connected to the electric circuit provided in the stacked layer substrate 81 via each of the relay leads 61 to 64, but may be alternatively connected via a plurality of relay leads 61 to 64.

In each of the above-described embodiments, the respective GND terminals of the respective semiconductor devices 1 to 5 may be alternatively connected to the housing of the motor MO, so that heat may be directly dissipated from the GND terminals to the housing of the motor MO. As a result, since the heat may be dissipated from the lead planes, the heat dissipation efficiency may be increased.

In the above-explained third embodiment, the respective leads 41 and 42 which constitute the M1 terminal may be commonly used so as to be arranged by one lead. Similarly, in the fifth embodiment, the respective leads 41 to 44, 133, and 134, which constitute the M1 terminal, the M2 terminal, and the Vdd terminal may be alternatively constituted by a commonly-used lead.

As explained in the fifth embodiment, such a connection mode that the first and third semiconductor chips 11 and 13 are connected to the relay leads 61 and. 63 by the ribbon leads 151 and 152 may be alternatively applied to, for example, the first embodiment, the second embodiment, and the fourth embodiment.

Similar to the above-explained second embodiment, also in the first embodiment and the third to fifth embodiments, since the respective leads 31 to 34, 41 to 44, 111, 112, 121 to 123, and 131 to 134 are bending-processed within the resin 90, the portions which are exposed from the resin 90 may be alternatively arranged on the same plane, respectively.

In the above-explained respective embodiments, the power elements have been employed as the respective semiconductor elements 11 to 14. Alternatively, an IGBT (insulated gate bipolar transistor), a bipolar power element may be employed.

Further, in order to improve heat dissipation characteristics, the respective leads 32 and 34 shown in FIG. 1 and FIG. 8 may be alternatively exposed from the resin 90; the respective leads 103 and 105 indicated in FIG. 4B, and the respective leads 111 and 112 represented in FIG. 6 may be alternatively exposed from the resin 90.

### Sixth Embodiment

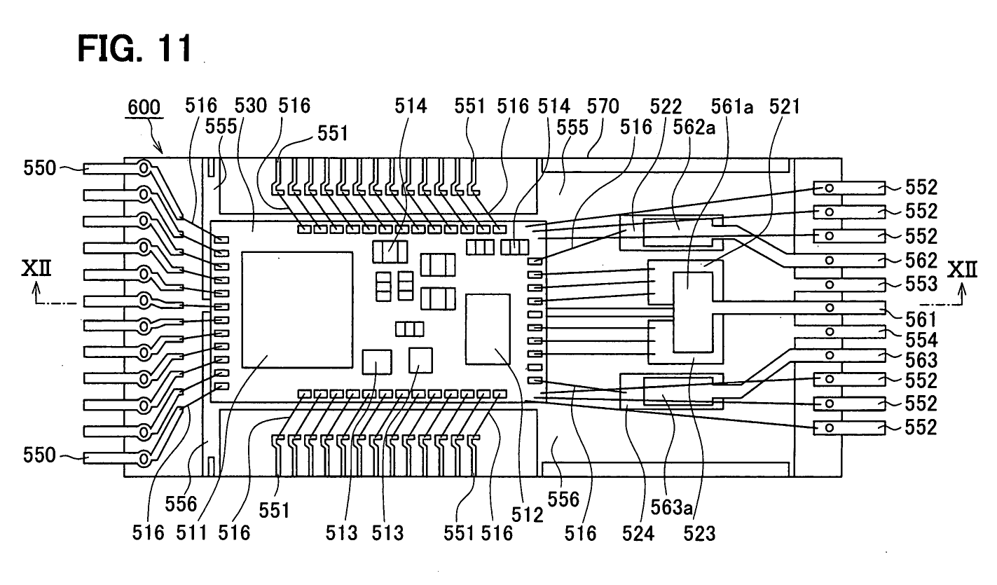

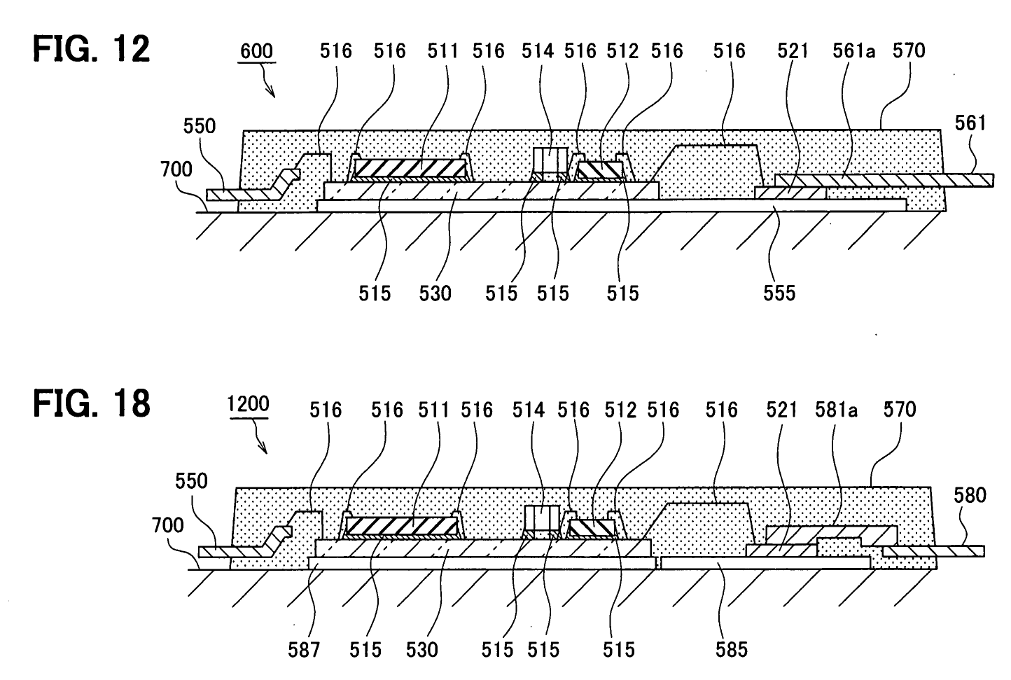

FIG. 11 schematically shows a plan view arrangement as to a front plane side of a load driving-purpose electronic apparatus 600 according to a sixth embodiment of the present invention. FIG. 12 is a sectional view for schematically indicating the load driving-purpose electronic apparatus 600, taken along a line XII-XII of FIG. 11. It should be understood that the sixth embodiment will describe that the load driving-purpose electronic apparatus 600 is applied to an HIC (Hybrid Integrated Circuit) which drives a driving motor of a power window of a vehicle. Also, FIG. 12 represents such a condition that this electronic apparatus 600 has been mounted on a case 700 of this driving motor.

As indicated in FIG. 11, the electronic apparatus 600 has been provided with first electronic elements 521 to 524, and second electronic elements 511 to 514 mounted on a wiring board 530. Leads 550 to 554, and 561 to 563 used to input/output an external signal have been provided around the first electronic elements 521 to 524, and the second electronic elements 511 to 514.

The first electronic elements 521 to 524 correspond to driving elements which drive the above-explained motor, and have been constituted by power MOS elements. Large currents used to drive a load flow through these power MOS elements 521 to 524, so that heat generation amounts of the power MOS elements 521 to 524 are large.

The second electronic elements 511 to 514 have been constituted by a microcomputer 511, a control IC 512, another IC chip 513, and a capacitor 514. Heat generation amounts of these second electronic elements 511 to 514 are smaller than those of the power MOS elements 521 to 524.

Also, as shown in FIG. 12, the second electronic elements 511 to 514 have been connected onto one plane of the wiring board 530 shown in FIG. 12 via a mount material 515 such as solder and a conductive adhesive agent.

In this case, as the wiring board 530, either a ceramics stacked layer board or a printed wiring board may be employed in which 3, or more layers have been stacked on each other. Concretely speaking, an alimina stacked layer wiring board made of alimina has been employed as this wiring board 530.

Also, as shown in FIG. 11, leads 550 to 554 and leads 561 to 563 have been provided around the wiring board 530 and the second electronic elements 521 to 524. The leads 550 to 554 constitute a portion of a first lead frame (will be explained later), whereas the leads 561 to 563 constitute a portion of a second lead frame (will be explained later). It should be understood that the first lead frame and the second lead frame have been manufactured by a normal lead frame material, namely, a plate material made of copper, or a 42 alloy. These first and second lead frames own superior heat conductivity characteristics.

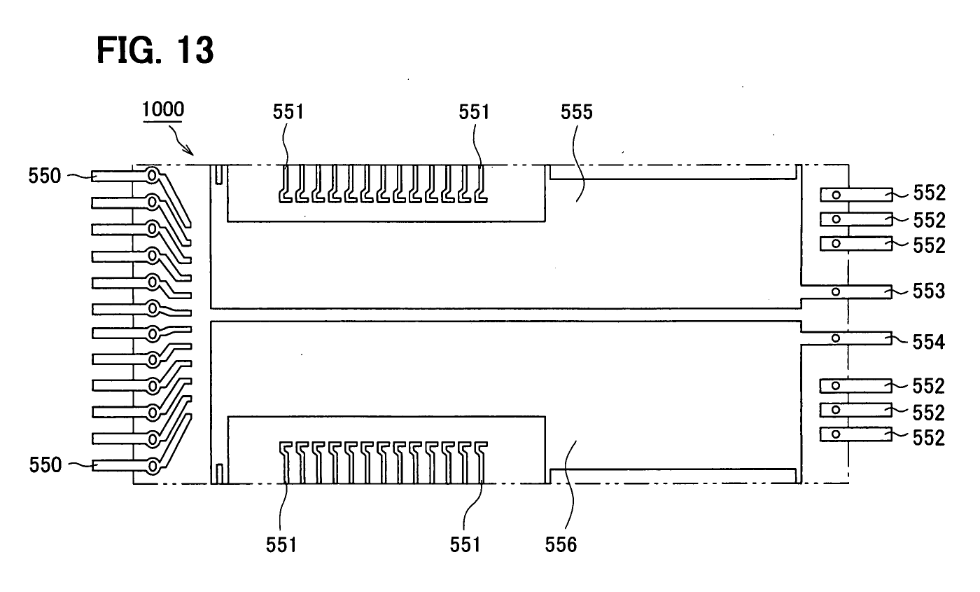

FIG. 13 schematically indicates a plan view structure of a first lead frame 1000. The first lead frame 1000 owns the leads 550 to 554, and component mounting regions 555 and 556.

The lead 550 located on the left side of FIG. 13 is an input terminal of the load driving-purpose electronic apparatus 600. This input terminal is used so as to input an external signal supplied from an external ECU, or the like to the microcomputer 511, and the like. In this example, the lead 550 is illustrated in the form of 12 pieces of leads.

Also, the lead 551 corresponds to a checking terminal employed so as to check operations of the microcomputer 511, while the lead 551 is illustrated in the form of 513 pieces of frames along an upper/lower direction of FIG. 13. Since checking operation as to operation characteristics of the microcomputer 511 cannot be accomplished only by checking the input/output terminals, signals provided in a half way are checked by these leads 551 in order to accomplish the checking operation.

Also, 6 pieces of leads 552 provided on a left side in FIG. 13 correspond to terminals which are used so as to input various sorts of signals from a motor of a power window. As the signals inputted from the motor of the power window, for example, there is a sensor signal produced from a sensor (not shown) which senses an abnormal rotation of the motor.

The leads 550 to 552 have been electrically connected to the wiring board 530 via bonding wires 516, and the wiring board 530 has been electrically connected to the power MOS elements 521 to 524 via bonding wires 516.

Also, the leads 553 and 554 provided on a right side of FIG. 13 correspond to terminals which are connected to the terminals of the motor of the power window. Large currents for driving the motor flow through these leads 553 and 554.

The component mounting regions 555 and 556 correspond to such areas which are used to mount the wiring board 530 where the power MOS elements 521 to 524 and the second electronic elements 511 to 514 have been mounted. The power MOS elements 521 and 522 have been mounted on one plane of the component mounting region 555, whereas the power MOS elements 523 and 524 have been mounted on one plane of the component mounting region 556. Also, the wiring board 530 on which the second electronic elements 511 to 514 have been mounted has been mounted in such a manner that this wiring board 530 bridges over one planes of these component mounting regions 555 and 556. As indicated in FIG. 12, other planes of the component mounting regions 555 and 556 have been provided in such a manner that these planes are exposed to the rear side of the load driving-purpose electronic apparatus 600. It should be understood that the rear side of this load driving-purpose electronic apparatus 600 is contacted to an insulating case 700 of the motor 800.

As previously explained, the second electronic components 511 to 514 are directly mounted on the component mounting regions 555 and 556, so that heat generated from the second electronic components 511 to 514 is dissipated via these component mounting regions 555 and 556 to an external portion.

Both the component mounting region 555 and the lead 553 have been made by the same material, and both the component mounting region 556 and the lead 554 have been made by the same material. Also, the component mounting region 555 has been connected to a drain electrode (not shown) of the power MOS element 521 via a mount material (not shown) such as solder and a conductive adhesive agent, and the component mounting region 556 has been connected to a drain electrode (not shown) of the power MOS element 522 via a mount material (not shown) such as solder and a conductive adhesive agent.

It should be understood that the component mounting regions 555 and 556 have been insulated from the wiring board 530 where the second electronic elements 511 to 514 have been mounted, and the component mounting region 555 has been insulated from the component mounting region 556.

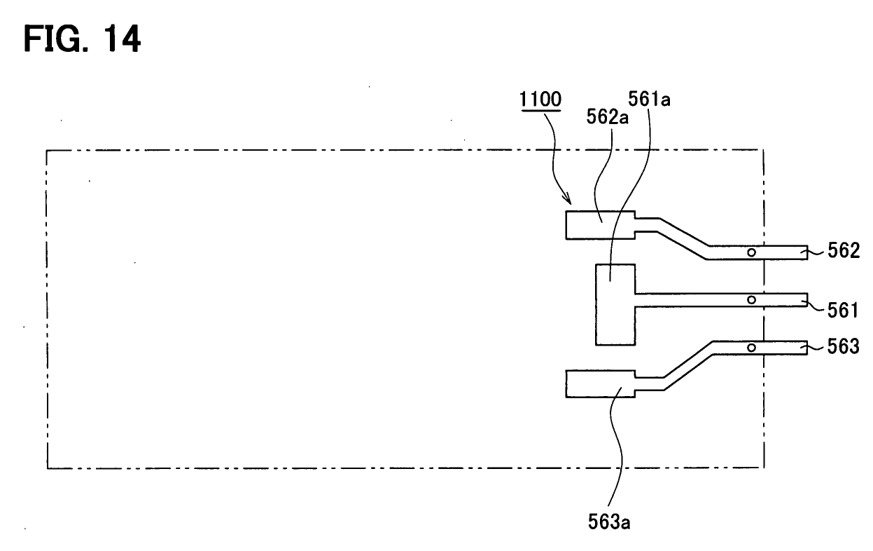

FIG. 14 is a plan view for schematically indicating a second lead frame 1100. The second lead frame 1100 owns contact regions 561a to 563a which are contacted to the leads 561 to 563, and the MOS elements 521 to 524. Both the lead 561 and the contact region 561a have been made of the same material, and, the lead 562, the contact region 562a, the lead 563 and the contact region 563a have been constituted by the same material.

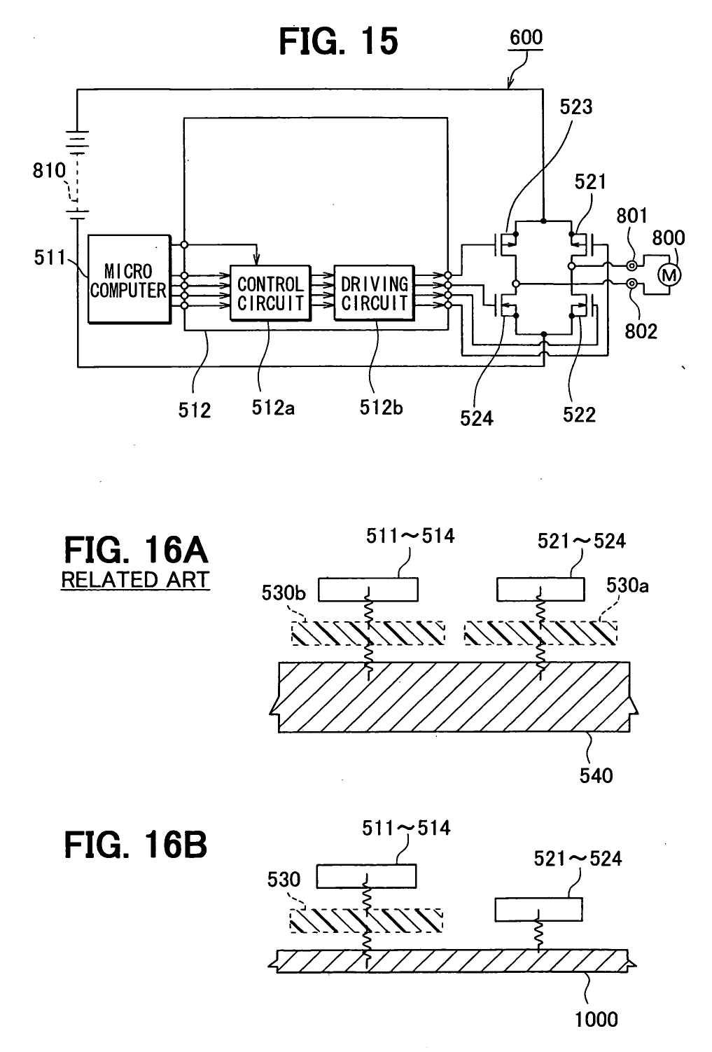

The leads 561 to 563 are connected to an external power supply 810 (refer to FIG. 15) which will be discussed later, and are employed so as to supply electric power to the power MOS elements 521 to 524. The lead 61 is connected to a power supply terminal of the external power supply 810, whereas the leads 562 and 563 are connected to a ground terminal of the external power supply 810 respectively.

As indicated in FIG. 11 and FIG. 12, the contact regions 561a to 563a are employed so as to electrically connect the leads 561 to 563 to respective source electrodes (not shown) of the power MOS elements 521 to 524, and also so as to dissipate heat of the power MOS elements 521 to 524 in combination with the component mounting regions 555 and 556 of the first lead frame.

The contact regions 561a to 563a have been electrically connected to the respective source electrodes (not shown) of the power MOS elements 521 to 524 via a mount material (not shown) such as solder and a conductive adhesive agent. The contact region 561a has been connected to the respective source electrodes (not shown) of the power MOS elements 521 and 523; the contact region 62a has been connected to the source electrode (not shown) of the power MOS element 522, and the contact region 563a has been connected to the source electrode (not shown) of the power MOS element 524.

The second lead frame 1100 has been provided in such a manner that the contact region 61a and the component mounting region 555 of the first lead frame 1000 directly sandwich the power MOS element 521; the contact region 561a and the component mounting region 556 of the first lead frame 1000 sandwich the power MOS element 523; the contact region 562a and the component mounting region 555 of the first lead frame 1000 sandwich the power MOS element 522; and the contact region 63a and the component mounting region 56 of the first lead frame 1000 directly sandwich the power MOS element 524.

The first lead frame 500, the second lead frame 600, the electronic elements 511 to 514, 521 to 524, the wiring board 530, and the bonding wire 516 have been sealed by using a mold resin 570 in such a manner that the contact regions 561a to 563a are externally exposed under such a condition that the power MOS elements 521 to 524 are directly sandwiched by the component mounting regions 555 and 556 of the first lead frame 1000 and the contact regions 561a to 563a of the second lead frame 1000.

This mold resin 570 is made of such a mold material as an epoxy series resin which is employed in a normal semiconductor package, and is molded by way of a transfer mold method using a molding die.

It should also be noted that the respective portions as to the leads 550 to 554 which constitute the first lead frame 1000, and the component mounting regions 555 and 556 have been coupled to the respective portions as to the leads 561 to 563 which constitute the second lead frame 1100, and the contact regions 561a to 563a by employing frame portions (not shown) respectively. These frame portions are cut to be separated from each other after mold sealing operation by the mold resin 570.

Also, this load driving-purpose electronic apparatus 600 is mounted under such a condition that the electronic apparatus 600 is insulated from a case 700 of a motor 800.

Next, a description is made of a circuit arrangement of the load driving-purpose electronic apparatus 600. FIG. 15 schematically indicates the circuit arrangement of this load driving-purpose electronic apparatus 600. Both the microcomputer 511, and the control IC 512 containing a control circuit 512a and a driving circuit 512b among the above-explained first electronic elements 511 to 514 constitute a major portion of this circuit arrangement. It should also be noted that other IC chip 513 and capacitor 514 have been provided in order to eliminate noise, and are omitted from FIG. 15.

Also, 4 pieces of the power MOS elements 521 to 524 constitute an H bridge circuit. Also, with respect to the load driving-purpose electronic apparatus 600, the above-described power window motor 800 for driving the window glass, and the external power supply 810 have been provided.

In such a circuit arrangement, a signal is transferred from a microcomputer (not shown) to the above-explained microcomputer 511 by way of a communication (for example, LIN), and in response to this instruction, the microcomputer 511 controls the respective power MOS elements 521 to 524 via the control circuit 512a and the driving circuit 512b. An output signal of the driving circuit 512b is entered to gates of the respective power MOS elements 521 to 524.

The power MOS elements 521 and 523 are P channel MOS transistors, whereas the power MOS elements 522 and 524 are N channel MOS transistors. The respective source electrodes (not shown) of the power MOS elements 521 and 523 have been electrically connected via the above-described lead 561 to the power supply terminal of the external power supply 810. The respective source electrodes (not shown) of the power MOS elements 522 and 524 have been electrically connected via the above-described leads 562 and 563 to the ground terminals of the external power supply 810.

Also, drain electrodes of the power MOS elements 521 and 522 have been connected via the component mounting region 555 and the lead 553 to one terminal 301 of the motor 300, whereas drain electrodes of the power MOS elements 523 and 524 have been connected via the component mounting region 555 and the lead 554 to the other terminal 802 of the motor 800.

In this case, the motor 800 causes the window glass of the vehicle to ascend and descend. When the motor 800 is stopped, all of the four power MOS elements 521 to 524 are brought into OFF statuses.

When the window glass ascends, two pieces of the power MOS elements 521 and 524 which are located on one diagonal in the H bridge circuit are brought into ON statuses, whereas two pieces of the power MOS elements 522 and 523 which are located on another diagonal thereof are brought into OFF statuses, so that a currant flows from one terminal 801 to the other terminal 802 in the motor 800.

When the window glass descends, two pieces of the power MOS elements 521 and 524 which are located on one diagonal in the H bridge circuit are brought into OFF statuses, whereas two pieces of the power MOS elements 522 and 523 which are located on another diagonal thereof are brought into ON statuses, so that a current flows from the other terminal 802 to one terminal 801 in the motor 800. In other words, when the window glass ascends and descends, the current flowing through the motor 800 is reversed by the H bridge circuit, and the rotation of the motor 800 is also reversed.

Also, when the window glass ascends and then has completely ascended, if the ON statuses of the power MOS elements 521 and 524 are held, then an excessively large current flows through the motor 300. As a result, large torque may be produced in the motor 800, and the motor 800 is brought into a sandwich condition.

When such a sandwich condition becomes, a sense signal for indicating an abnormal rotation state of the motor 800 is inputted from the motor 300 to the control circuit 512a, and then, the signal is switched by the control circuit 512a. As a result, the torque of the motor 800 is decreased, and thus, it is possible to avoid the sandwich condition by the window glass.

In accordance with the above-explained arrangement, the first and second lead frames 1000 and 1100, and also, the power MOS elements 521 to 524 are provided in such a manner that the component mounting regions 555 and 556 are exposed to the external portion under such a condition that the power MOS elements 521 to 524 for driving the motor 800 is sandwiched by the component mounting regions 555 and 556 of the first lead frame 1000, and the contact regions 561a and 563a of the second lead frame 1100 from both sides. As a result, heat generated from the power MOS elements 521 to 524 is dissipated via the component mounting regions 555 and 556 to the external portion, so that the heat dissipation characteristic can be secured. As a result, such a heat sink is no longer required which is needed in the conventional apparatus, and thus, the electronic apparatus can be made compact.

Also, since the power MOS elements 521 to 524 are sandwiched by both the component mounting regions 555 and 56 of the first lead frame 1000, and the contact regions 561a to 563a of the second lead frame 1100, the heat generated from the power MOS elements 521 to 524 can be dissipated to the external portion via the first and second component mounting regions 555, 556, 561a to 563a, and the plural leads 552, 561 to 563, so that the heat dissipation characteristic can be further improved.

FIG. 16A and FIG. 16B indicate thermal resistance models. FIG. 16A shows a thermal resistance model of the conventional apparatus shown in FIG. 28, and FIG. 16B represents a thermal resistance model of the load driving-purpose electronic apparatus 600. It should also be noted that only the first lead frame 1000 is represented in FIG. 16B, and the second lead frame 1100 is omitted.

As shown in FIG. 16A, in the conventional apparatus, the wiring board 530b on which the second electronic elements 511 to 514 have been mounted, and the wiring board 530a on which the power MOS elements 521 to 524 have been mounted have been separately prepared. The wiring boards 530a and 530b have been mounted on the heat sink 540 respectively.

On the other hand, in the load driving-purpose electronic apparatus 600 shown in FIG. 16B, the wiring board 530b on which the second electronic elements 511 to 514 have been mounted has been mounted on the first lead frame 1000, whereas the power MOS elements 521 to 524 have been directly mounted on the first lead frame 1000.

In the arrangement of the conventional apparatus shown in FIG. 16A, the wiring board 530a is present between the power MOS elements 521 to 524 and the heat sink 540, so that the thermal resistance between the power MOS elements 521 to 524 and the heat sink 540 is large. However, in the arrangement of the load driving-purpose electronic apparatus 600 shown in FIG. 16B, the power MOS elements 521 to 524 have been directly mounted on the first lead frame 1000, so that the thermal resistance between the power MOS elements 521 to 524, and the heat sink 540 becomes small. Also, this load driving-purpose electronic apparatus 600 has been made of such a structure that the heat is furthermore dissipated from the upper portions of the power MOS elements 521 to 524 by the second lead frame 1100 in order to improve the heat dissipation characteristic.

### Seventh Embodiment

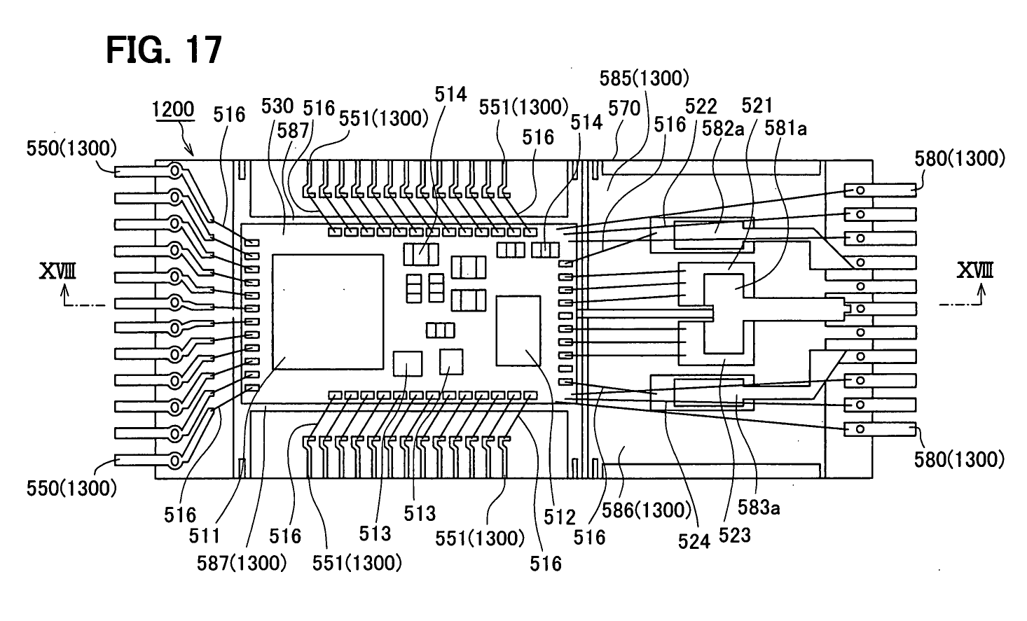

FIG. 17 shows an arrangement of a load driving-purpose electronic apparatus 1200 according to a seventh embodiment of the present invention. The above-explained sixth embodiment has represented such an arrangement that the heat of the power MOS elements 521 to 524 is dissipated in such a manner that the power MOS elements 521 to 524 are directly sandwiched by two pieces of the lead frames 1000 and 1100. In the load driving-purpose electronic apparatus 1200 of this seventh embodiment, such an arrangement is employed in which the power MOS elements 521 to 524 are directly sandwiched by one lead frame 1300, and also, frame members 581a to 583a which are mounted to this lead frame 1300. It should be understood that the same reference numerals shown in the sixth embodiment will be employed as those for indicating the same components of the seventh embodiment, explanations thereof are omitted, and different points will be mainly described.

The load driving-purpose electronic apparatus 1200 has been equipped with a lead frame 1300 which has leads 550, 551, 580, and component mounting regions 585 to 587.

Such terminals corresponding to the respective leads 552 to 554, and 561 to 563 shown in the sixth embodiment are contained in the lead 580 shown in a right side of FIG. 17. In other words, the lead 580 contains terminals for inputting various sorts of signals from the motor 800 of the power window, terminals which are to be connected to the terminals 801 and 802 of the motor 800, and terminals for supplying electric power to the power MOS elements 521 to 524.

The component mounting regions 585 to 587 correspond to such regions for mounting thereon a wiring board 30 on which the power MOS elements 521 to 524 and the second electronic elements 511 to 514 have been packaged. As indicated in FIG. 18, the rear plane sides of the component mounting regions 585 to 587 have been provided in such a manner that these component mounting regions 585 to 587 are exposed to the rear side of the load driving-purpose electronic apparatus 1300. Such a wiring board 530 has been mounted in which the power MOS elements 521 and 522 are mounted on the component mounting region 585; the power MOS elements 523 and 524 are mounted on the component mounting region 586; and the second electronic elements 511 to 514 are mounted on the component mounting region 587.

The lead frame 1300 has been provided in such a manner that both the frame members 581a to 583a and the component mounting regions 585 and 586 directly sandwich the power MOS elements 521 to 524 from both sides. In other words, both the frame member 581a and the component mounting region 585 sandwich the power MOS element 521; both the frame member 581a and the component mounting region 586 sandwich the power MOS element 523; both the frame member 582a and the component mounting region 585 sandwich the power MOS element 522; and both the frame member 583a and the component mounting region 586 directly sandwich the power MOS element 524.

Also, the power MOS elements 521 to 524 have been electrically connected to the component mounting regions 585 to 587 via a mount material (not shown) such as solder and a conductive adhesive agent. Also, the frame members 581a to 583a have been electrically connected to the respective source electrodes (not shown) of the power MOS elements 521 to 524 via a mount material (not shown) such as solder and a conductive adhesive agent.

In accordance with the above-explained arrangement, the load driving-purpose electronic apparatus 1200 is arranged in such a manner that the component mounting regions 585 and 586 are exposed to the external portion under such a condition that the power MOS elements 521 to 524 for driving the motor 800 is sandwiched by the component mounting regions 585 and 586 of the lead frame 1300 and the frame members 581a to 583a from both sides. As a result, heat generated from the power MOS elements 521 to 524 is dissipated via the component mounting regions 585 and 586 to the external portion, so that the heat dissipation characteristic can be secured. As a result, such a heat sink is no longer required which is needed in the conventional apparatus, and thus, the electronic apparatus can be made compact.

### Eighth Embodiment

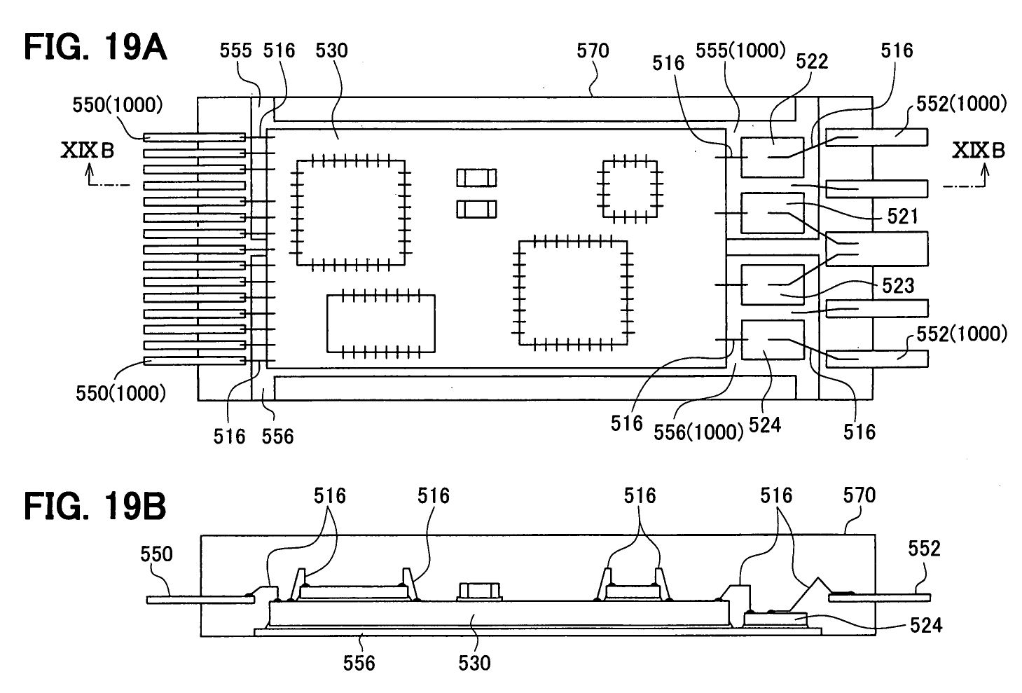

FIG. 19A schematically indicates a plan view structure as to a front plane side of a load driving-purpose electronic apparatus according to an eighth embodiment of the present invention. FIG. 19B schematically shows a sectional view of the load driving-purpose electronic apparatus, taken along a line XIX-XIX of FIG. 19A. In the above-described sixth embodiment, while the power MOS elements 521 to 524 are mounted on one plane sides of the component mounting regions 555 and 556, two pieces of the lead frames 1000 and 1100, and the power MOS elements 521 to 524 are sealed by the mold resin 570 in such a manner that the other plane sides of the component mounting regions 555 and 556 are exposed to the external portion under such a condition that the power MOS elements 521 to 524 are sandwiched by the component mounting regions 55 and 56, and the contact regions 561a to 563a from both sides.

The eighth embodiment exemplifies such an arrangement that while the power MOS elements 521 to 524 are mounted on one plane sides of the component mounting regions 555 and 556, the lead frame 1000, and the power MOS elements 521 to 524 are sealed by the mold resin 570 in such a manner that the other plane sides of the component mounting regions 555 and 556 are exposed to the external portion while the power MOS elements 521 to 524 are not sandwiched from both sides. Also, the load driving-purpose electronic apparatus of this eighth embodiment is not equipped with the lead 551 functioning as the checking terminal.

As shown in FIG. 19A, the power MOS elements 521 and 522 have been mounted on one plane of the component mounting region 555, whereas the power MOS elements 523 and 524 have been mounted on one plane of the component mounting region 556.

Also, the lead frame 1000 has leads 550 and 552, and the component mounting regions 555 and 556.

Also, both the lead frame 1000 and the power MOS elements 521 to 524 have been sealed by the mold resin 570 in such a manner that the other plane sides of the component mounting regions 555 and 556 are exposed to the external portion.

As previously explained, while the power MOS elements 521 to 524 are mounted on one plane sides of the component mounting regions 555 and 556, the lead frame 1000 and the power MOS elements 521 to 524 are sealed by the mold resin 570 in such a manner that the other plane sides of the component mounting regions 555 and 556 are exposed to the external portion. As a result, heat generated from the power MOS elements 521 to 524 is dissipated via the component mounting regions 555 and 556 to the external portion, so that the heat dissipation characteristic can be secured.

### Ninth Embodiment

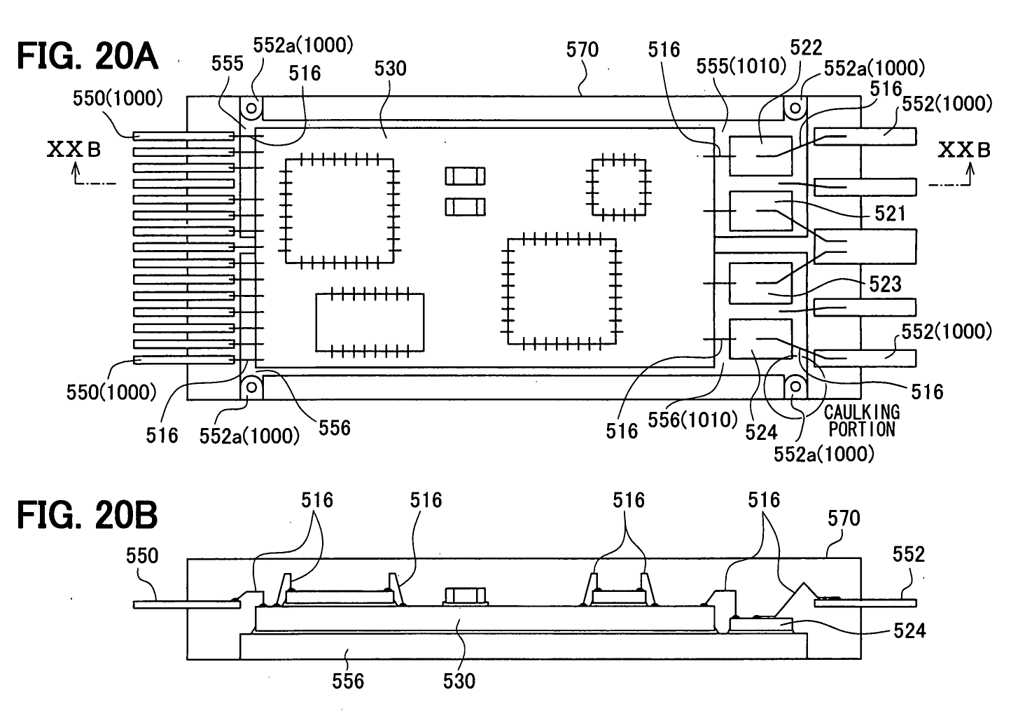

FIG. 20A schematically indicates a plan view structure as to a front plane side of a load driving-purpose electronic apparatus according to a ninth embodiment of the present invention. FIG. 20B schematically shows a sectional view of the load driving-purpose electronic apparatus, taken along a line XXB-XXB of FIG. 20A. In the above-described eighth embodiment, the thicknesses of the leads 550 and 552 are equal to those of the component mounting regions 555 and 556. In this ninth embodiment, thicknesses of the component mounting regions 555 and 556 are made thicker than thicknesses of the leads 550 and 552 in order to improve heat dissipation characteristics of the power MOS elements 521 to 524.

In other words, the leads 550 and 552, and also, the component mounting regions 555 and 556 have been arranged by employing lead frames having different thicknesses.

To this end, a caulking portion (lead portion 552a) has been provided on the third lead frame 1000 for coupling the leads 550 and 552 to each other at 4 positions, while these four caulking portions are used to fix a first lead frame 1010 for coupling the component mounting regions 555 and 556. The first and third lead frames 1010 and 1000 are fixed by this caulking portion (lead portion 552a), and are cut away after the mold sealing operation.

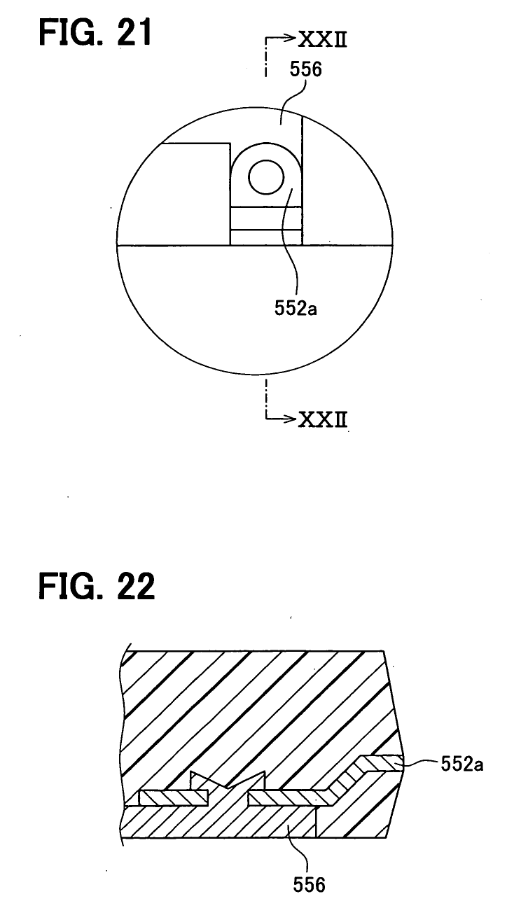

FIG. 21 is an enlarged view for indicating the caulking portion of FIG. 20A. FIG. 22 is a sectional structure of the caulking portion, taken along a line XXII-XXII of FIG. 21.

The lead portion 552a shown in FIG. 21 and FIG. 22 has been formed in the third lead frame 1000 as same as the leads 550 and 552, while an opening hole has been formed in a center portion of this lead portion 552a. Also, projection portions have been formed at 4 portions of the peripheral portions of the component mounting regions 555 and 556.

After the projection portions formed on the component mounting regions 555 and 556 have been inserted into the opening holes of the lead portions 552a, since portions projected from the opening holes are caulked, the lead portions 552a are caulked so as to be fixed on the component mounting regions 555 and 556 of the first lead frame 1000.

As explained above, the first and third lead frames 1010 and 500 have been caulked so as to be fixed by the lead portion 552a of the third lead frame 1000.

### Tenth Embodiment

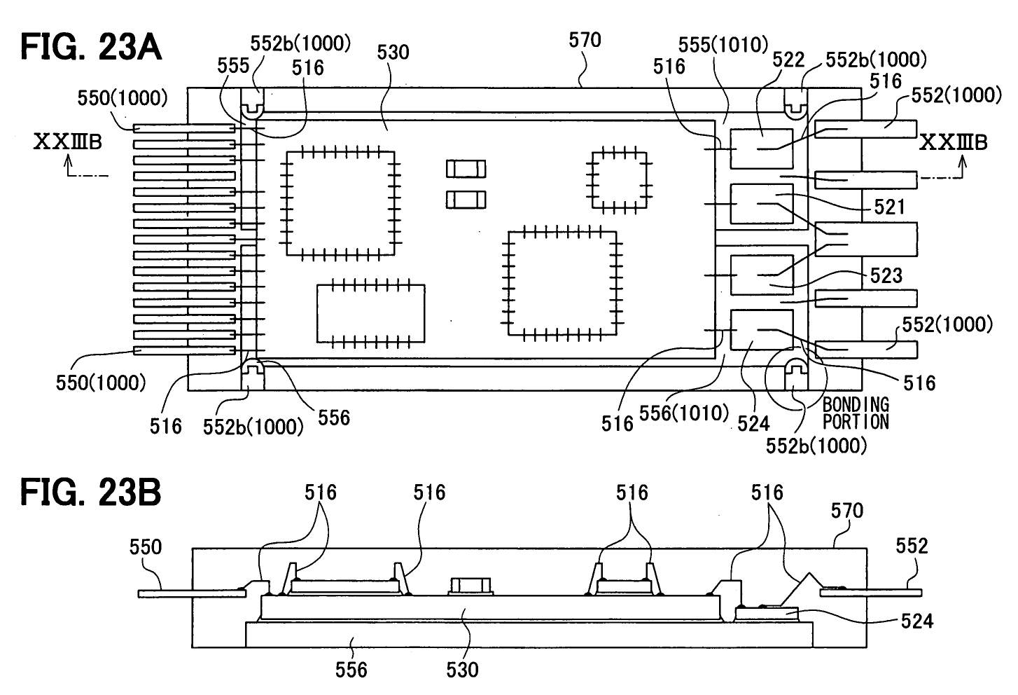

FIG. 23A schematically indicates a plan view structure as to a front plane side of a load driving-purpose electronic apparatus according to a tenth embodiment of the present invention. FIG. 23B schematically shows a sectional view of the load driving-purpose electronic apparatus, taken along a line XXIIIB-XXIIIB of FIG. 23A. The above-explained ninth embodiment has exemplified that the component mounting regions 555 and 556 of the first lead frame 1010 are caulked so as to be fixed by the lead portion 552a formed on the third lead frame 1000 for coupling the leads 550 and 552. In this tenth embodiment, the component mounting regions 555 and 556 of the third lead frame 1010 are adhered so as to be fixed by the lead portion 552a formed on the third lead frame 1000.

As shown in FIG. 23B, thicknesses of the component mounting regions 555 and 556 of the first lead frame 1010 are made thicker than thicknesses of the leads 550 and 552 of the third lead frame 1000.

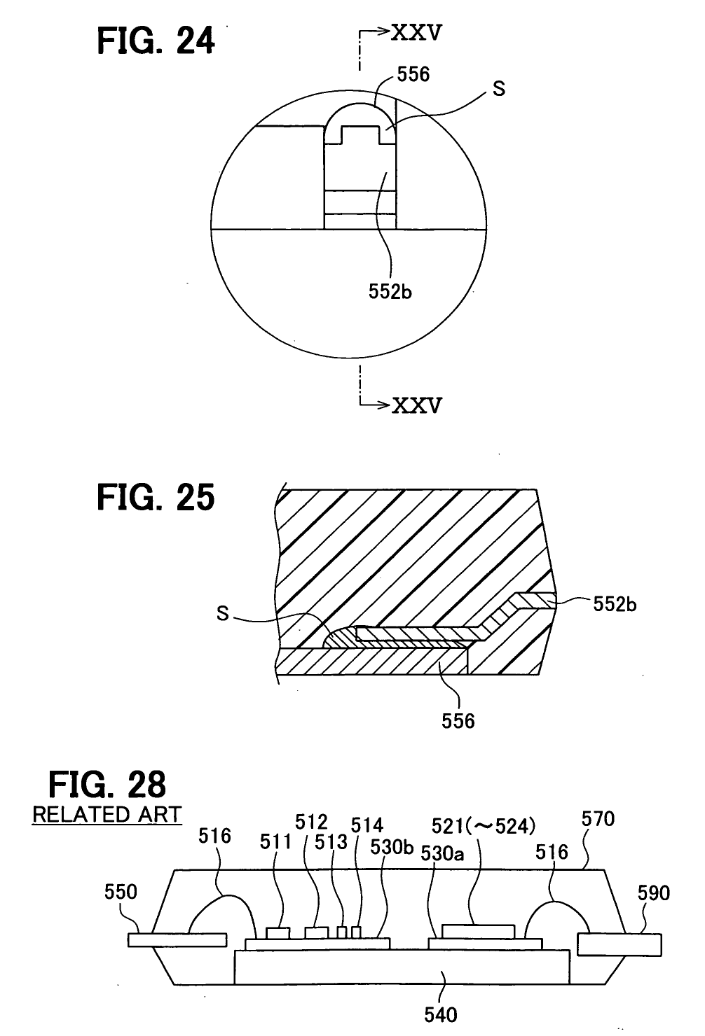

FIG. 24 is an enlarged view for indicating an adhering portion of FIG. 23A. FIG. 25 is a sectional structure of the adhering portion, taken along a line XXV-XXV of FIG. 24.

A lead portion 552b shown in FIG. 24 and FIG. 25 has been formed in the third lead frame 1000 as same as the leads 550 and 552. These lead portions 552b are adhered so as to be fixed onto the component mounting regions 555 and 556 by employing an adhesive agent “S” such as silicone rubber.

It should also be noted that both the third lead frame 510 for coupling the leads 550 and 552 to each other, and the first lead frame 1010 for coupling the component mounting regions 555 and 556 to each other are adhered so as to be fixed by these lead portions 552b, and are cut away after the mold sealing operation.

As previously explained, the first and third lead frames 1010 and 1030 are adhered so as to be fixed by the lead portion 552a of the third lead frame.

### Eleventh Embodiment

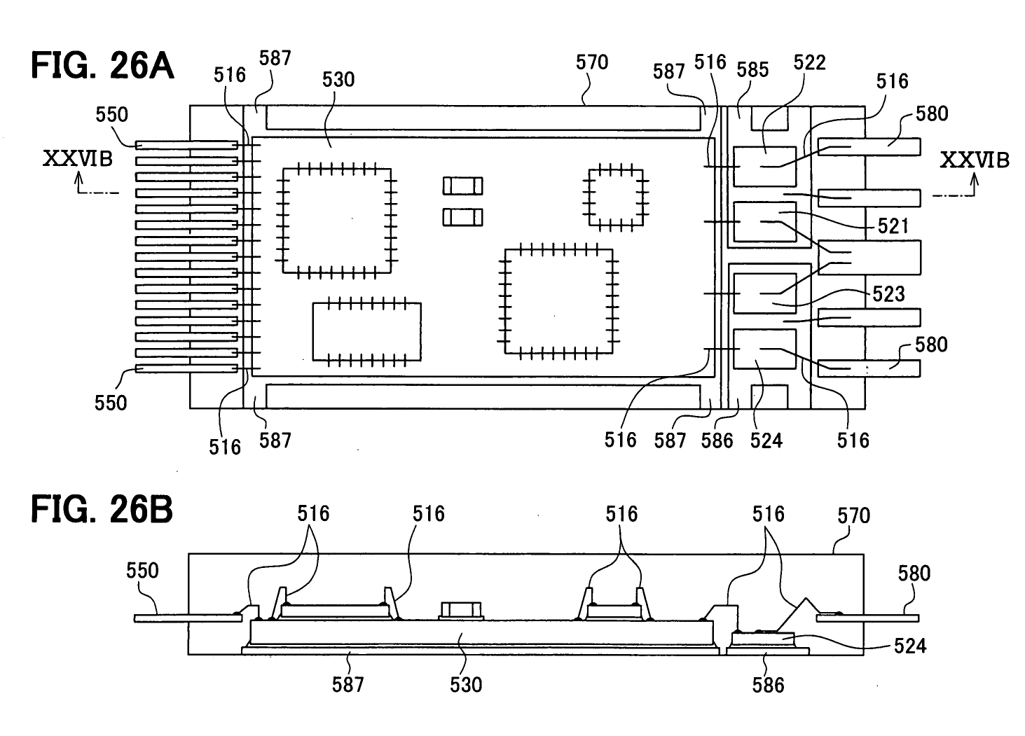

FIG. 26A schematically indicates a plan view strict as to a front plane side of a load driving-purpose electronic apparatus according to an eleventh embodiment of the present invention. FIG. 26B schematically shows a sectional view of the load driving-purpose electronic apparatus, taken along a line XXVIB-XXVIB of FIG. 26A. The above-explained seventh embodiment has exemplified such an arrangement. That is, while the wiring board 30 on which the second electronic elements 511 to 514 have been packaged are mounted on one plane of the component mounting region 587, and also, while the power MOS elements 521 to 524 are mounted on one plane sides of the component mounting regions 555 and 556, the frame members 581a to 583a, the lead frame 1300, and the power MOS elements 521 to 524 are sealed by the mold resin 570 in such a manner that the other plane sides of the component mounting regions 585 to 587 are exposed to the external portion under such a condition that the power MOS elements 521 to 524 are sandwiched by the component mounting regions 585 and 586, and the frame members 581a to 583a from each other. In this eleventh embodiment, while the power MOS elements 521 to 524 are not sandwiched from both sides, the lead frame 1300, the frame members 581a to 583a, and the power MOS elements 521 to 524 are sealed by the mold resin 570 in such a manner that the other plane sides of the component mounting regions 585 to 587 are exposed to the external portion.

As previously explained, the load driving-purpose electronic apparatus of the eleventh embodiment may be arranged as follows: That is, while the wiring board 530 on which the second electronic elements 511 to 514 have been packaged are mounted on one plane of the component mounting region 587, and also, while the power MOS elements 521 to 524 are mounted on one plane sides of the component mounting regions 585 and 586, the lead frame 1300, the frame members 581a to 583a, and the power MOS elements 521 to 524 are sealed by the mold resin 570 in such a manner that the other plane sides of the component mounting regions 585 and 587 are exposed to the external portion.

It should also be understood that the component mounting region 585 is connected to one terminal 801 of the motor 800 shown in FIG. 15, whereas the component mounting region 586 is connected to the other terminal 802 of the motor 800. Also, in the component mounting region 587, the potential has been brought into a grounded condition, or a floating condition. As previously explained, different potentials for every component mounting regions may be held.

### Twelfth Embodiment

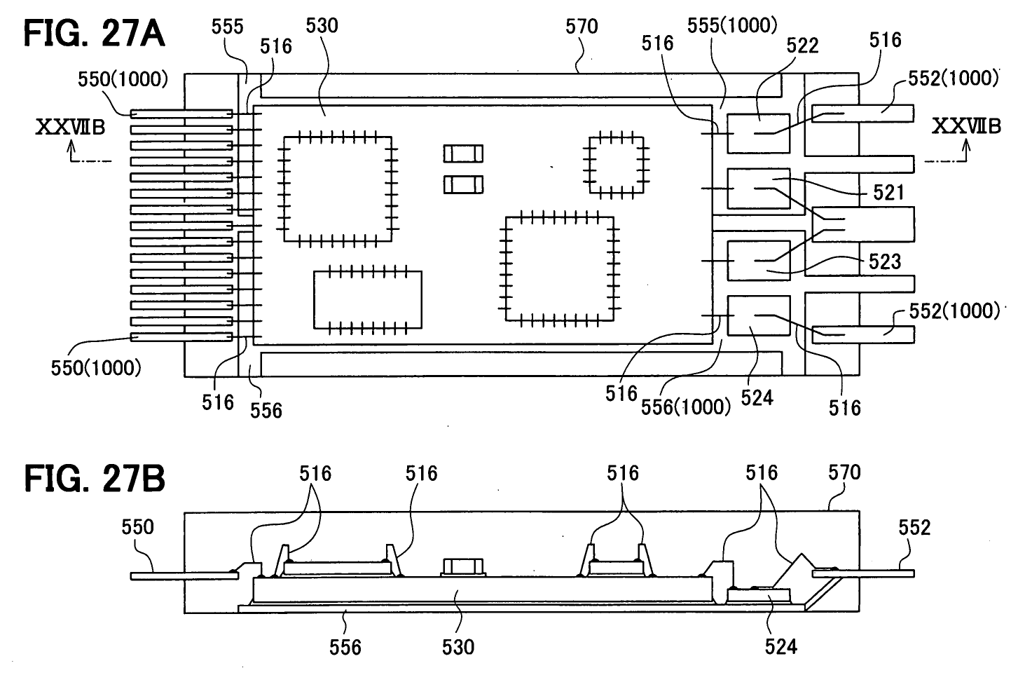

FIG. 27A schematically indicates a plan view structure as to a front plane side of a load driving-purpose electronic apparatus according to a twelfth embodiment of the present invention. FIG. 27B schematically shows a sectional view of the load driving-purpose electronic apparatus, taken along a line XXVIIB-XXVIIB of FIG. 27A. The above-explained eighth embodiment has exemplified such an arrangement that the component mounting regions 555 and 556 are separately constituted from the lead 552. In this twelfth embodiment, portions of the component mounting regions 555 and 556 constitute a partial lead of the plural leads 552.

That is to say, a second lead 552 and a fourth lead 552 defined from the plural leads 552 shown in FIG. 27A have been arranged in such an assumption that partial regions of the component mounting regions 555 and 556 are extended.

As previously explained, since the partial leads of the plural leads 552 are arranged by the partial regions of the component mounting regions 555 and 556, a large current may flow, as compared with such a case that the component mounting regions 555 and 556 are electrically connected to the lead 552 by the bonding wires.

### Modifications

The above-described embodiments have explained such a case that the load driving-purpose electronic apparatus are applied to the HICs for driving the driving motors of the power windows of the vehicle. However, the above embodiments are not limited only to this use field, but may be applied to, for example, an apparatus for driving a relay, or the like.

Also, the above-described embodiment modes have explained such a case that the motor 800 is driven by the 4 power MOS elements 521 to 524. Alternatively, the above embodiments may be applied to such a case that a load is driven by employing, for example, a single power element.

Further, the above-explained embodiments have described such an example as to the load driving-purpose electronic apparatus for driving the motor as the load. However, the above embodiments are not limited only to the motor, but may be applied to such a load driving-purpose electronic apparatus which drives, for instance, a relay as a load.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A semiconductor device comprising:
first to fourth vertical type semiconductor elements, each of which includes a semiconductor substrate having first and second surfaces, wherein each semiconductor element further includes a first electrode disposed on the first surface of the substrate and a second electrode disposed on the second surface of the substrate, and wherein each semiconductor element is capable of flowing current between the first and second electrodes;
a metallic lead for functioning as a wiring and a heat sink;
a resin mold for molding the semiconductor elements and a part of the metallic lead;
a circuit board;
an electric circuit disposed on one side of the circuit board; and
an electronic chip disposed on the one side of the circuit board, wherein the electronic chip is capable of driving and controlling each semiconductor element through the electric circuit, wherein
the first to fourth semiconductor elements are arranged to be a stack construction in the resin mold,
the first to fourth semiconductor elements provide a H-bridge circuit, and
each of the first and second electrodes in each semiconductor element is directly connected to the metallic lead so that heat generated in the semiconductor element is radiated through the metallic lead.

2. The device according to claim 1, wherein
each semiconductor element is electrically connected to the electric circuit through a wire and a relay lead.

3. The device according to claim 1, wherein
each semiconductor element is a MOS type power element.

4. The device according to claim 1, wherein
the metallic lead includes a plurality of first and second plate leads and a plurality of ribbon leads,
each plate lead has a thickness larger than that of the ribbon lead,
the first electrode of each semiconductor element is directly connected to one end of the ribbon lead,
the other end of the ribbon lead is connected to the first plate lead, and
the second electrode of each semiconductor element is directly connected to the second plate lead.

5. The device according to claim 4, wherein
the first electrode of the first semiconductor element is connected to a first one of the first plate leads through the ribbon lead,
the first electrode of the third semiconductor element is connected to a second one of the first plate leads through the ribbon lead,
the first one of the first plate leads and the second one of the first plate leads are bonded each other so that they provide a power source terminal,
the second electrode of the first semiconductor element is directly connected to a first one of the second plate leads,
the second electrode of the second semiconductor element is directly connected to a second one of the second plate leads,
the first one of the second plate leads and the second one of the second plate leads are bonded each other so that they provide a first load terminal,
the second electrode of the third semiconductor element is directly connected to a third one of the second plate leads,
the second electrode of the fourth semiconductor element is directly connected to a fourth one of the second plate leads,
the third one of the second plate leads and the fourth one of the second plate leads are bonded each other so that they provide a second load terminal,
the first electrode of the second semiconductor element is connected to a third one of the first plate leads through the ribbon lead so that the third one of the first plate leads provides a first ground terminal, and
the first electrode of the fourth semiconductor element is connected to a fourth one of the first plate leads through the ribbon lead so that the fourth one of the first plate leads provides a second ground terminal.

6. The device according to claim 4, wherein
the second electrode of the first semiconductor element is directly connected to a first one of the second plate leads,
the second electrode of the second semiconductor element is directly connected to a second one of the second plate leads,
the first one of the second plate leads and the second one of the second plate leads are bonded each other so that they provide a first load terminal,
the second electrode of the third semiconductor element is directly connected to a third one of the second plate leads,
the second electrode of the fourth semiconductor element is directly connected to a fourth one of the second plate leads,
the third one of the second plate leads and the fourth one of the second plate leads are bonded each other so that they provide a second load terminal,
the first electrode of the first semiconductor element is connected to a first common one of the first plate leads through the ribbon lead,
the first electrode of the third semiconductor element is connected to the first common one of the first plate leads through the ribbon lead,
the first semiconductor element and the third semiconductor element are horizontally arranged on a same plane,
the first electrode of the second semiconductor element is connected to a second common one of the first plate leads through the ribbon lead,
the first electrode of the fourth semiconductor element is connected to the second common one of the first plate leads through the ribbon lead, and
the second semiconductor element and the fourth semiconductor element are horizontally arranged on another same plane.

7. The device according to claim 6, wherein
the first common one of the first plate leads has a T-shape with a first horizontal part and a first vertical part,
the first semiconductor element is disposed on one side of the first horizontal part, and the third semiconductor element is disposed on the other side of the first horizontal part,
the second common one of the first plate leads has a T-shape with a second horizontal part and a second vertical part, and
the second semiconductor element is disposed on one side of the second horizontal part, and the fourth semiconductor element is disposed on the other side of the second horizontal part.

8. The device according to claim 5, wherein
the first one of the first plate leads and the second one of the first plate leads are bonded each other in such a manner that a bonding surface of the first one of the first plate leads has a concavity, and a bonding surface of the second one of the first plate leads has a convexity, so that the concavity is engaged with the convexity,
the first one of the second plate leads and the second one of the second plate leads are bonded each other in such a manner that a bonding surface of the first one of the second plate leads has a concavity, and a bonding surface of the second one of the second plate leads has a convexity, so that the concavity is engaged with the convexity, and
the third one of the second plate leads and the fourth one of the second plate leads are bonded each other in such a manner that a bonding surface of the third one of the second plate leads has a concavity, and a bonding surface of the fourth one of the second plate leads has a convexity, so that the concavity is engaged with the convexity.

9. The device according to claim 4, wherein
the first electrode of the first semiconductor element is connected to a first common one of the first plate leads through the ribbon lead,
the first electrode of the third semiconductor element is connected to the first common one of the first plate leads through the ribbon lead,
the first common one of the first plate leads provides a power source terminal,
the second electrode of the first semiconductor element is directly connected to a first common one of the second plate leads,
the second electrode of the second semiconductor element is directly connected to the first common one of the second plate leads,
the first common one of the second plate leads provides a first load terminal,
the second electrode of the third semiconductor element is directly connected to a second common one of the second plate leads,
the second electrode of the fourth semiconductor element is directly connected to the second common one of the second plate leads,
the second common one of the second plate leads provides a second load terminal,
the first electrode of the second semiconductor element is connected to a second one of the first plate leads through the ribbon lead so that the second one of the first plate leads provides a first ground terminal, and
the first electrode of the fourth semiconductor element is connected to a third one of the first plate leads through the ribbon lead so that the third one of the first plate leads provides a second ground terminal.

10. The device according to claim 5, wherein
each of the first and second plate leads includes an exposing portion, which is exposed from the resin mold, and
each of the first and second plate leads further includes a bending portion in the resin mold so that the exposing portions of the first and second plate leads are arranged on a same plane.

11. The device according to claim 1, wherein
the metallic lead includes a plurality of first and second leads,
each first lead includes a plate lead portion and a ribbon lead portion,
the plate lead portion has a thickness larger than that of the ribbon lead portion,
each second lead provides a plate lead,
the first electrode of each semiconductor element is directly connected to the ribbon lead portion of the first lead, and
the second electrode of each semiconductor element is directly connected to the second lead.

12. The device according to claim 11, wherein
the first electrode of the first semiconductor element is connected to a ribbon lead portion of a first one of the first leads,
the first electrode of the third semiconductor element is connected to a ribbon lead portion of a second one of the first leads,
a plate lead portion of the first one of the first leads and a plate lead portion of the second one of the first leads are bonded each other so that they provide a power source terminal,
the second electrode of the first semiconductor element is directly connected to a first one of the second leads,
the second electrode of the second semiconductor element is directly connected to a second one of the second leads,
the first one of the second leads and the second one of the second leads are bonded each other so that they provide a first load terminal,
the second electrode of the third semiconductor element is directly connected to a third one of the second leads,
the second electrode of the fourth semiconductor element is directly connected to a fourth one of the second leads,
the third one of the second leads and the fourth one of the second leads are bonded each other so that they provide a second load terminal,
the first electrode of the second semiconductor element is connected to a ribbon lead portion of a third one of the first leads so that a plate lead portion of the third one of the first leads provides a first ground terminal, and
the first electrode of the fourth semiconductor element is connected to a ribbon lead portion of a fourth one of the first leads so that a plate lead portion of the fourth one of the first leads provides a second ground terminal.

13. The device according to claim 12, wherein
each of the first and second leads includes an exposing portion, which is exposed from the resin mold, and
each of the first and second leads further includes a bending portion in the resin mold so that the exposing portions of the first and second leads are arranged on a same plane.

14. The device according to claim 12, wherein
the first one of the first leads and the second one of the first leads are bonded each other in such a manner that a bonding surface of the first one of the first leads has a concavity, and a bonding surface of the second one of the first leads has a convexity, so that the concavity is engaged with the convexity,
the first one of the second leads and the second one of the second leads are bonded each other in such a manner that a bonding surface of the first one of the second leads has a concavity, and a bonding surface of the second one of the second leads has a convexity, so that the concavity is engaged with the convexity, and
the third one of the second leads and the fourth one of the second leads are bonded each other in such a manner that a bonding surface of the third one of the second leads has a concavity, and a bonding surface of the fourth one of the second leads has a convexity, so that the concavity is engaged with the convexity.

15. An electronic device for driving a load comprising:
a first lead frame having an element mounting region and an exposing region;
a driving element for driving a load and disposed on one side of the element mounting region of the first lead frame;
a second lead frame having a contact region, wherein the contact region contacts the driving element in such a manner that the contact region of the second lead frame and the element mounting region of the first lead frame sandwich the driving element; and
a resin mold molding the first and second lead frames and the driving element, wherein
the exposing region of the first lead frame is exposed from the resin mold.

16. An electronic device for driving a load comprising:
a lead frame having an element mounting region and an exposing region;
a driving element for driving a load and disposed on one side of the element mounting region of the lead frame;
a frame member having a contact region, wherein the contact region contacts the driving element in such a manner that the contact region of the frame member and the element mounting region of the lead frame sandwich the driving element; and
a resin mold molding the lead frame, the frame member and the driving element, wherein
the exposing region of the lead frame is exposed from the resin mold.

17. An electronic device for driving a load comprising:
a lead frame having an element mounting region and an exposing region;
a driving element for driving a load and disposed on one side of the element mounting region of the lead frame; and
a resin mold molding the lead frame and the driving element, wherein
the exposing region of the lead frame is exposed from the resin mold.

18. The device according to claim 17, wherein
the lead frame includes a plurality of leads for inputting/outputting an electric signal, and
the element mounting region of the lead frame has a part, which provides a part of the leads.

19. An electronic device for driving a load comprising:
a first lead frame having an element mounting region and an exposing region;
a driving element for driving a load and disposed on one side of the element mounting region of the first lead frame;
a second lead frame having a plurality of leads for inputting/outputting an electric signal; and
a resin mold molding the element mounting region of the first lead frame, the leads of the second lead frame and the driving element, wherein
the exposing region of the first lead frame is exposed from the resin mold.

20. The device according to claim 19, wherein
the element mounting region of the first lead frame has a thickness equal to or larger than that of each lead of the second lead frame.

21. The device according to claim 20, wherein
the second lead frame includes a caulking portion for fixing the first lead frame.
